(19) United States
(12) Patent Application Publication
(10) Pub. No.: US 2026/0363045 A1
(43) Pub. Date: Nov. 12, 2026

(54) METHOD OF MANUFACTURING HIGH ASPECT RATIO VERTICAL STRUCTURES IN SEMICONDUCTOR DEVICES

(71) Applicant: Samsung Electronics Co., Ltd., Suwon-si (KR)

(72) Inventors: Mingi Choi, Suwon-si (KR); Soyeon Yoo, Suwon-si (KR); Gumhye Jeon, Suwon-si (KR); Sukkoo Hong, Suwon-si (KR)

(21) Appl. No.: 19/652,186

(22) Filed: Apr. 20, 2026

(30) Foreign Application Priority Data
May 9, 2025 (KR) 10-2025-0060454

(51) Int. Cl. H10W 20/00; H10D 64/01; H10P 50/68

(52) U.S. Cl. CPC H10W 20/089; H10D 64/021; H10P 50/683; H10W 20/057

(57) ABSTRACT

A method of manufacturing semiconductor devices includes: sequentially forming an interlayer insulating layer and an upper insulating layer on a substrate; forming first open regions by sequentially penetrating through the upper insulating layer and the interlayer insulating layer; applying a first organic material and filling the first openings; changing solubility according to a position of the first organic material; selectively removing the first organic material on the upper insulating layer; applying a second organic material on the upper insulating layer; changing solubility of the second organic material in a first region overlapping the first openings by providing light to the second organic material; forming open regions by removing the first organic material of the first openings and the second organic material of the first region together; and forming a vertical structure filling the open regions.

### CROSS-REFERENCE TO RELATED APPLICATIONS

This application claims benefit of priority to Korean Patent Application No. 10-2025-0060454 filed on May 9, 2025, in the Korean Intellectual Property Office, the disclosure of which is incorporated herein by reference in its entirety.

### BACKGROUND

As semiconductor devices become smaller and more integrated, three-dimensional arrays of two-dimensionally disposed elements or elements having a three-dimensional form have been proposed. For example, as one of the methods of increasing the data storage capacity of a semiconductor device, a semiconductor device including three-dimensionally disposed memory cells instead of two-dimensionally disposed memory cells has been proposed. Additionally, through-plugs or vertical capacitors have been proposed as vertical structures.

In order to form vertical structures having a large aspect ratio, a photoresist is applied, developed, and etched multiple times. When there are openings having a large aspect ratio under the photoresist, since the photoresist is not applied uniformly, a process margin decreases in the light irradiation for development to increase a defect rate.

### SUMMARY

The present disclosure relates to a method of manufacturing semiconductor devices.

An aspect of the present disclosure is to provide a method of manufacturing semiconductor devices in which open regions for vertical structures in a highly integrated vertical semiconductor device are filled with a photoresist, and an additional photo process is performed to secure a process margin in light irradiation.

An aspect of the present disclosure is to provide a method of manufacturing semiconductor devices in which open regions having a large aspect ratio are filled with an organic material including a photoresist and the solubility of the organic material inside the open regions and outside the open regions may be controlled differently through light and heat.

In an example implementation, provided is a method of manufacturing semiconductor devices including sequentially forming an interlayer insulating layer and an upper insulating layer on a substrate; forming first openings by sequentially penetrating through the upper insulating layer and the interlayer insulating layer; applying a first organic material and filling the first openings, wherein the first organic material includes a first portion within the first openings and a second portion on the upper insulating layer; changing solubility of the first organic material according to a position of the first organic material; selectively removing the second portion of the first organic material on the upper insulating layer; applying a second organic material on the upper insulating layer; changing solubility of the second organic material in a first region overlapping the first openings by providing light to the second organic material; forming open regions by removing the first portion of the first organic material within the first openings and the second organic material in the first region together; and forming a vertical structure filling the open regions.

In an example implementation, provided is a method of manufacturing semiconductor devices including a method of manufacturing one or more semiconductor devices, the method comprising: forming an interlayer insulating layer on a substrate, forming an upper insulating layer on the interlayer insulating layer; forming first openings by penetrating through the upper insulating layer and the interlayer insulating layer; applying a first organic material; filling the first openings with the first organic material, wherein the first organic material includes a first portion within the first openings and a second portion on the upper insulating layer; changing solubility of the first organic material according to a position of the first organic material; selectively removing the second portion of the first organic material on the upper insulating layer; applying a second organic material on the upper insulating layer; changing solubility of the second organic material in a first region overlapping the first openings by providing light to the second organic material; forming open regions by removing the first portion of the first organic material within the first openings and the second organic material in the first region together; and forming a vertical structure filling the open regions, wherein the first organic material includes a polymer resin, a solubility converting agent, and a solvent, wherein the solubility converting agent includes a photo-base generator and a thermal acid generator.

In an example implementation, provided is a method of manufacturing semiconductor devices including: forming a mold structure by alternately stacking sacrificial insulating layers and interlayer insulating layers in a first direction; forming first openings from an upper surface of the mold structure; applying a first organic material and filling the first openings, wherein the first organic material includes a first portion within the first openings and a second portion on the mold structure; changing solubility of the first organic material according to a position of the first organic material; selectively removing the second portion of the first organic material on the mold structure; applying a photoresist on the mold structure; changing solubility of the photoresist in a first region overlapping a portion of the first openings by providing light to the photoresist; forming second openings by removing the first region of the photoresist and the first portion of the first organic material within the first openings under the first region together; forming sacrificial layers filling the second openings; replacing the sacrificial insulating layers with gate electrodes; and forming contact plugs in contact with the gate electrodes by removing the sacrificial layer.

According to example implementations, in a vertical semiconductor memory device for high integration, holes having a high aspect ratio for vertical structures are filled with a photoresist, and then a subsequent process is performed, so that planarization may be performed by cleaning without an additional planarization process.

Accordingly, since the process may be performed at once within the photo equipment, the manufacturing process may be simplified. Additionally, since the planarization is maintained, a Depth of focus (DOF) margin of After Develop Inspection (ADI) is secured when applying the photoresist for the subsequent photo process, so that the process reliability may be improved.

Advantages and effects of the present disclosure are not limited to the foregoing content and may be more easily understood in the process of describing a specific example implementation of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic cross-sectional view of a semiconductor device according to example implementations;

FIGS. 2 and 3 are flowcharts illustrating a method of manufacturing the semiconductor device of FIG. 1;

FIGS. 4A, 4B, 4C, 4D, 4E, 4F, 4G, 4H and 4I are schematic cross-sectional views illustrating a method of manufacturing the semiconductor device of FIG. 1;

FIG. 5 is a flowchart illustrating another example implementation of a method of manufacturing the semiconductor device of FIG. 1;

FIGS. 6A, 6B, and 6C are schematic cross-sectional views illustrating a method of manufacturing the semiconductor device of FIG. 5;

FIG. 7 is a schematic cross-sectional view of a semiconductor device according to example implementations;

FIG. 8 is a flowchart illustrating a method of manufacturing the semiconductor device of FIG. 7;

FIGS. 9A, 9B, 9C, 9D, 9E, 9F, 9G, 9H, 9I, 9J, 9K, 9L, 9M, 9N, 9O, 9P and 9Q are schematic cross-sectional views illustrating a method of manufacturing the semiconductor device of FIG. 8;

FIG. 10 is a flowchart illustrating another method of manufacturing the semiconductor device of FIG. 7; and

FIGS. 11A, 11B, 11C, 11D, 11E, 11F are schematic cross-sectional views illustrating a method of manufacturing the semiconductor device of FIG. 10.

### DETAILED DESCRIPTION

Hereinafter, example implementations of the present disclosure will be described with reference to the accompanying drawings. Hereinafter, the terms ‘above,’ ‘upper portion,’ ‘upper surface,’ ‘below,’ ‘lower portion,’ ‘lower surface,’ ‘side surface,’ and the like, may be understood as being indicated based on the accompanying drawing, except that they are indicated by drawing references and referred to separately.

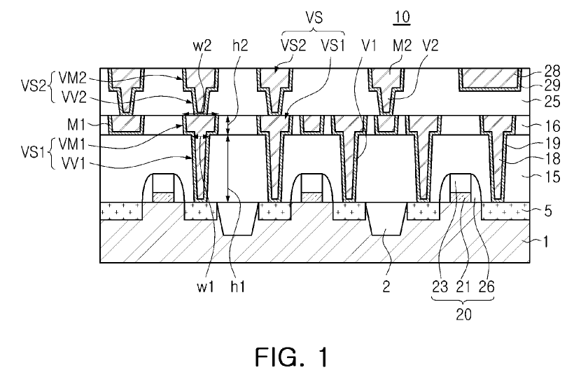

Hereinafter, with reference to FIG. 1, a semiconductor device according to example implementations will be described.

A semiconductor device 10 may include a substrate 1, impurity regions 5 and element isolation regions 2 within the substrate 1, circuit elements 20 disposed on the substrate 1, a first interlayer insulating layer 15, a first upper insulating layer 16, and a first via V1 and a first interconnection layer M1. The semiconductor device 10 may further include a second interlayer insulating layer 25 on the first upper insulating layer 16, and may further include second vias V2 and a second interconnection layer M2 penetrating through the second interlayer insulating layer 25.

The semiconductor device 10 may include vertical structures VS on the substrate 1.

The substrate 1 may have an upper surface extending in an X-direction and a Y-direction. The substrate 1 may define an active region by the isolation element regions 2. Impurity regions 5 including impurities may be disposed in a portion of the active region. The substrate 1 may include a semiconductor material, for example, a group IV semiconductor, a group III-V compound semiconductor, or a group II-VI compound semiconductor. The substrate 1 may be provided as a bulk wafer or an epitaxial layer. For example, the substrate 1 may be bulk silicon or a silicon-on-insulator (SOI).

The circuit elements 20 may include a planar transistor. Each of the circuit elements 20 may include a gate dielectric layer 21, a gate electrode 23 on the gate dielectric layer 21, and a gate spacer 26 on a side surface of the gate electrode 23, which are included in a gate structure. Impurity regions 5 may be disposed as source/drain regions within the substrate 1 on both sides of the gate electrode 23. The circuit elements 20 may have a gate structure which is a stack structure having an element height from the substrate 1.

A substrate insulating layer may be disposed along an upper surface of the substrate 1 and a profile of the circuit elements 20. The substrate insulating layer may include a semiconductor oxide, and may include silicon oxide and silicon oxycarbide.

The first interlayer insulating layer 15 may be disposed on the circuit elements 20. The first interlayer insulating layer 15 is formed to have a thickness h1, sufficient to cover the circuit elements 20, and may have a flat upper surface. The first interlayer insulating layer 15 may be formed of an insulating material.

The first upper insulating layer 16 may be disposed on the first interlayer insulating layer 15. The first upper insulating layer 16 may include the same material as the first interlayer insulating layer 15, but is not limited thereto, and may have a thickness h2 smaller than that of the first interlayer insulating layer 15.

An etch stop layer may be further disposed between the first interlayer insulating layer 15 and the first upper insulating layer 16. The etch stop layer includes a material having etch selectivity with the first interlayer insulating layer 15 and the first upper insulating layer 16, and may be a nitride-based insulating layer. The etch stop layer may have a thickness smaller than that of the first interlayer insulating layer 15 and the first upper insulating layer 16.

The first vias V1 and the first interconnection layer M1 may be disposed to penetrate through the first interlayer insulating layer 15 and the first upper insulating layer 16. A structure of the first interconnection layer M1 may be variously changed. The first interconnection layer M1 and the first vias V1 may be electrically connected to the circuit elements 20 and the impurity regions 5. The first interconnection layer M1 and the first vias V1 may be referred to as a lower interconnection structure or a circuit interconnection structure. The first vias V1 may have a columnar shape, and the first interconnection layer M1 may have a line shape. An electrical signal may be applied to the circuit elements 20 by the first vias V1 and the first interconnection layer M1. Some of the first vias V1 may also be connected to the gate electrode 23 and the impurity regions 5. A resistance relief layer doped with a high concentration of impurities may be disposed in a contact region between the impurity regions 5 and the first vias V1. The first interconnection layer M1 may be connected to or spaced apart from the first vias V1, and may be disposed in a plurality of layers. The first interconnection layer M1 and the first vias V1 may include a conductive material layer 18. For example, the conductive material layer 18 may include tungsten (W), copper (Cu) and aluminum (Al), and the conductive material layer 18 may be surrounded by a diffusion barrier 19. The diffusion barrier 19 may include a metal nitride such as tungsten nitride, titanium nitride, tantalum nitride, or the like, but the present disclosure is not limited thereto.

The second interlayer insulating layer 25 may be disposed on the first upper insulating layer 16 so that an upper surface thereof may be flat. The second interlayer insulating layer 25 may include the same material as the first interlayer insulating layer 15, and may be configured to include multiple insulating layers such as the first interlayer insulating layer 15 and the first upper insulating layer 16.

The second vias V2 and the second interconnection layer M2 may be disposed by penetrating through the second interlayer insulating layer 25.

A structure of the second interconnection layer M2 may be variously changed. The second interconnection layer M2 M1 and the second vias V2 may be electrically connected to the first interconnection layer M1. The second interconnection layer M2 and the second vias V2 may be referred to as upper interconnection structures. The second vias V2 may have a pillar shape, and the second interconnection layer M2 may have a line shape. The second vias V2 and the second interconnection layer M2 may apply an electrical signal to the circuit element 20 through the first interconnection layer M1. The second interconnection layer M2 may be connected to or spaced apart from the second vias V2 and may be disposed in a plurality of layers. The second interconnection layer M2 and the second vias V2 may include a conductive material layer 28. For example, the conductive material layer 28 may include tungsten (W), copper (Cu) and aluminum (Al), and the conductive material layer 28 may be surrounded by a diffusion barrier 29. The diffusion barrier 29 may include a metal nitride such as tungsten nitride, titanium nitride and tantalum nitride, but the present disclosure is not limited thereto.

The second interlayer insulating layer 25 may further include an etch stop layer between regions in which the second interconnection layer M2 and the second vias V2 are respectively disposed.

The vertical structures VS may be disposed on the substrate 1. The vertical structures VS may include a first vertical structure VS1 and a second vertical structure VS2 that are continuous in a Z-direction.

The first vertical structure VS1 may include a first vertical portion VV1 and a first horizontal portion VM1.

The first vertical portion VV1 may penetrate through the first interlayer insulation layer 15 and may be a vertical structure having an inclined side surface having a width w1 of an upper end thereof greater than a width of a lower end thereof. The first vertical portion VV1 may be a structure having a large aspect ratio, and the width w1 of the upper end thereof may be much smaller than a length h1 in the Z-direction.

The first vertical portion VV1 may be in the form of a column, but the present disclosure is not limited thereto, and the first vertical portion VV1 may be a structure of a circular type, a square type, or a bar type in which one end is narrow, when viewed from the top.

The first vertical portion VV1 may be disposed to overlap the first horizontal portion VM1 in the Z-direction.

The first horizontal portion VM1 may cover an upper end of the first vertical portion VV1, and a width of a lower end of the first horizontal portion VM1 may be greater than the width w1 of the upper end of the first vertical portion VV1, and a width w2 of an upper surface of the first horizontal portion VM1 may be greater than the width of the lower end of the first horizontal portion VM1. Accordingly, inclination directions of the respective side surfaces of the first horizontal portion VM1 and the first vertical portion VV1 may be substantially the same. It may be understood that the first horizontal portion VM1 is disposed to completely cover the first vertical portion VV1 in the Z-direction, and the first vertical portion VV1 protrudes in the Z-direction from a lower surface of the first horizontal portion VM1. A length h2 of the first horizontal portion VM1 in the Z-direction may be smaller than a length h1 of the first vertical portion VV1 in the Z-direction. In this case, an aspect ratio of the first vertical portion VV1 may be larger than an aspect ratio of the first horizontal portion VM1.

The first vertical structure VS1 may be disposed substantially on the same level as the first vias V1 and the first interconnection layer M1. For example, an upper end of the first vertical portion VV1 may be disposed on the same level as an upper end of the first vias V1, and a lower end of the first vertical portion VV1 may be disposed on the same level as a lower end of the first vias V1. Accordingly, the length h1 of the first vertical portion VV1 in the Z-direction may be substantially the same as the length of the first vias V1 in the Z-direction.

The upper surface of the first horizontal portion VM1 may be disposed on the same level as an upper surface of the first interconnection layer M1, and the lower end of the first horizontal portion VM1 may be disposed on the same level as a lower surface of the first interconnection layer M1. Accordingly, the length h2 of the first horizontal portion VM1 in the Z-direction may be substantially the same as a length of the first interconnection layer M1 in the Z-direction.

The second vertical structure VS2 may be disposed on the first vertical structure VS1.

The second vertical structure VS2 may, similarly to the first vertical structure VS1, include a second vertical portion VV2 corresponding to the second vias V2, and a second horizontal portion VM2 corresponding to the second interconnection layer M2.

Depending on the thickness of the second interlayer insulating layer 25 and the first interlayer insulating layer 15, vertical lengths of the first vertical structure VS1 and the second vertical structure VS2 may be changed, and may be implemented as multilayer vertical structures penetrating through multilayer interlayer insulating layers 15 and 25.

Accordingly, the vertical structure VS may be understood as a coupling structure in which individual vertical structures VS1 and VS2 penetrating through respective interlayer insulation layers 15 and 25 are electrically and physically connected in the Z-direction.

Such a vertical structure VS may include only the first vertical structure VS1, but may be implemented as a two-stage structure VS1 and VS2 as illustrated in FIG. 1, and may also be implemented as a multi-stage structure.

In FIG. 1, materials such as the first vias V1 and the first interconnection layer M1 are described as being included as a material in the vertical structure, but the present disclosure is not limited thereto, and various materials may be filled depending on the characteristics of the vertical structure VS. For example, the vertical structure VS may function as a contact plug, and may be understood as a vertical stack structure of multilayer vias and multilayer interconnection layers.

Alternatively, the vertical structure VS may be a vertical capacitor. Depending on the material of the capacitor, when the vertical structure VS is a metal-insulating layer-metal (MIM) capacitor, an interlayer insulating layer between the two vertical structures may function as a capacitor dielectric layer, but the present disclosure is not limited thereto. When the vertical structure VS is a vertical capacitor, each vertical structure VS may be formed as a long bar-type structure in a direction, parallel to an upper surface of the substrate, but the present disclosure is not limited thereto, and the vertical structure VS may be implemented with two electrodes spaced apart from each other.

Alternatively, when the vertical capacitor is a silicon-insulating layer-silicon (SIS) capacitor, the inside of the two vertical structures VS may be filled with silicon instead of a metal material, and accordingly, the diffusion barrier may be omitted.

The semiconductor device 10 may include a vertical structure VS for various functions, and the vertical structure VS may have a structure in which vertical portions VV1 and VV2 having a narrow area, which penetrate through thick interlayer insulating layers 15 and 25, are formed, and then horizontal portions VM1 and VM2 are formed, and then the corresponding material is embedded at the same time.

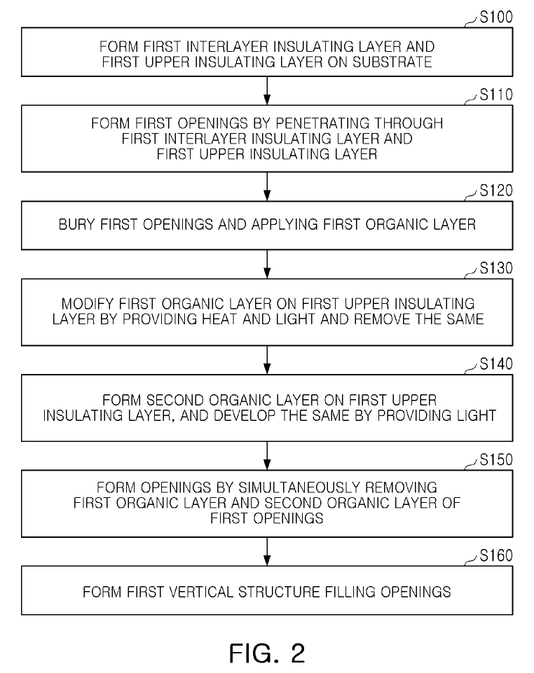

Hereinafter, a method of manufacturing the semiconductor device 10 of FIG. 1 will be described with reference to FIGS. 2 - 4.

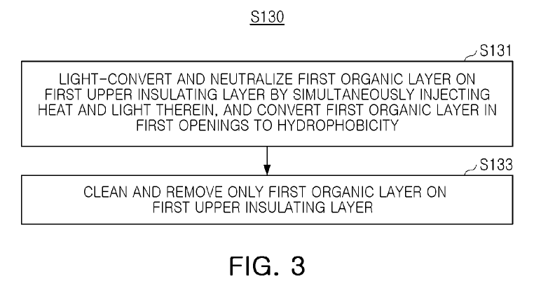

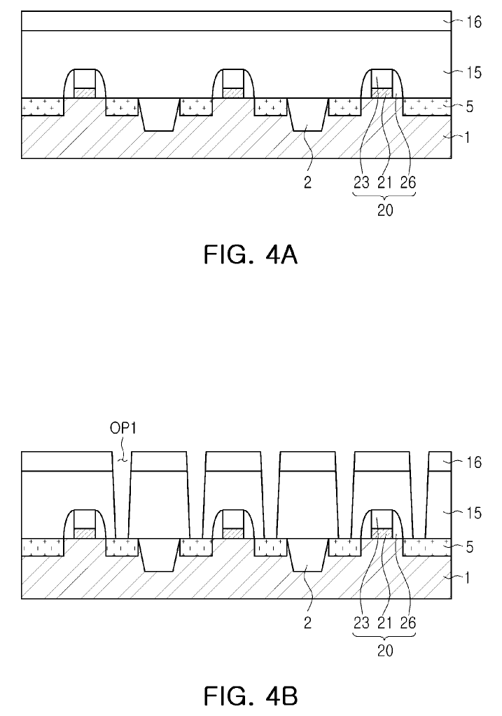

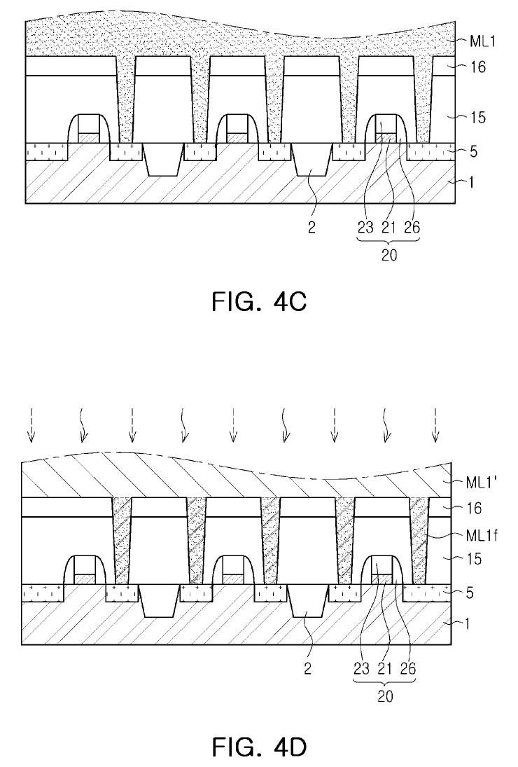

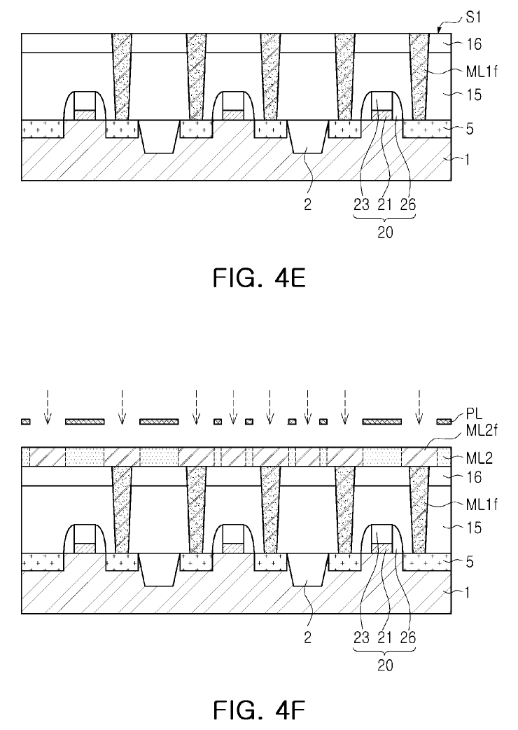

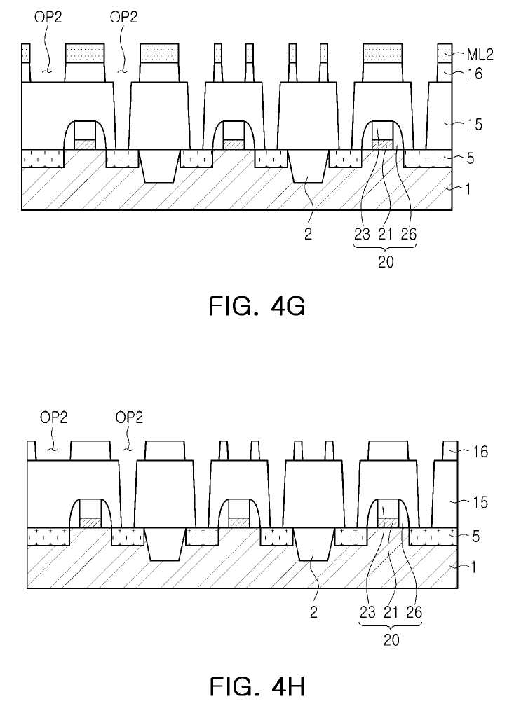

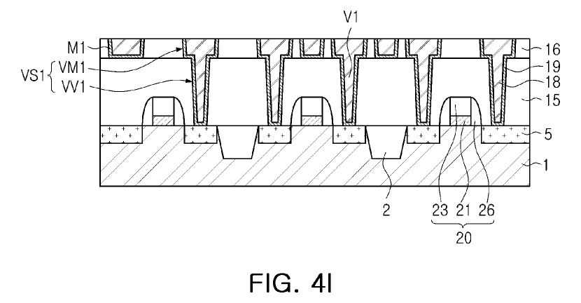

FIGS. 2 - 3 are flowcharts illustrating a method of manufacturing the semiconductor device of FIG. 1. FIG. 2 is a flowchart illustrating an entire semiconductor device of FIG. 1, and FIG. 3 is a flowchart illustrating an operation of modifying the first organic layer of FIG. 2. FIGS. 4A - 4I are schematic cross-sectional views illustrating a method of manufacturing a semiconductor device according to example implementations, and are cross-sectional views corresponding to the semiconductor device of FIG. 1.

Referring to FIGS. 2 and 4A, circuit elements may be formed on a substrate, and a first interlayer insulating layer 15 and a first upper insulating layer 16 may be formed to cover the circuit elements 20 (S100).

An element isolation region 2 may be formed in the substrate 1. The element isolation region 2 may define an active region of each circuit element 20.

The element isolation region 2 may be formed through a shallow trench isolation (STI) process. The shallow trench isolation process may be a process of forming isolation trenches in the substrate 1 and filling the isolation trenches with an insulating material such as silicon oxide.

When the element isolation region 2 is formed in the substrate 1, a gate dielectric layer 21 and a gate electrode 23 may be sequentially formed over the entire substrate 1, and the stack structure may be removed except for a region in which a gate structure of each circuit element 20 is formed.

Gate spacers 26 may be formed on both sidewalls of the gate structure formed in this manner. Next, an ion implantation process may be performed to form an impurity region 5, which is a source/drain region, within the substrate 1 on both sides of each gate structure. Accordingly, circuit elements 20 may be completed.

A substrate insulating layer such as silicon oxide or silicon oxycarbide may be formed on a front surface of the substrate 1 on which the circuit elements 20 are formed by heat-treating the substrate 1.

A first interlayer insulating layer 15 may be formed to cover the front surface of the substrate 1, and a first upper insulating layer 16 may be formed to cover the first interlayer insulating layer 15.

The first interlayer insulating layer 15 and the first upper insulating layer 16 may be formed by depositing silicon oxide, TetraEthylOrthoSilicate (TEOS) oxide, SiOCH or SiOC by a first thickness h1, but the present disclosure is not limited thereto.

An etch stop layer may be further formed between the first interlayer insulating layer 15 and the first upper insulating layer 16. The etch stop layer may be an insulating material including at least one of AlN, SiN, SiBN or SiCN. The first interlayer insulating layer 15 and the first upper insulating layer 16 may be formed to have a flat upper surface.

As illustrated in FIG. 2 and FIG. 4B, first openings regions OP1 penetrating from an upper surface of the first upper insulating layer 16 to the upper surface of the substrate may be formed (S110).

The first openings OP1 may be formed in positions in which the first vias V1 or the first vertical portions VV1 are formed, and the first openings OP1 may be holes having a large aspect ratio so that the first openings OP1 may continuously penetrate through the first upper insulating layer 16, the etch stop layer and the first interlayer insulating layer 15 and extend to the substrate 1.

The first openings OP1 may be formed so that the upper surface of the substrate 1 is exposed, and may be formed in positions of the first vertical portions VV1 of the first vertical structure VS1, respectively.

Referring to FIGS. 2 - 4C, a first organic layer ML1 may be prepared, and the first organic layer ML1 may be applied onto the first upper insulating layer 16 to fill the first openings OP1 (S120).

The first organic layer ML1 is a photoresist organic layer, and may include a positive polymer resin, a photo-base generator and a thermal acid generator as a solubility converting agent, and a solvent.

The positive polymer resin may be decomposed under an action of a base, thereby increasing the solubility of the photoresist in an acidic developer. The positive polymer resin is insoluble or poorly soluble in the acidic developer, but a base generated after light irradiation may change a polarity by a deprotection reaction of a polymer side chain, or the like, and may thus become soluble in the acidic developer. The positive polymer resin may be decomposed under the action of an acid, thereby increasing the solubility of the photoresist in an alkaline developer. The positive polymer resin is insoluble or poorly soluble in an alkaline developer, but the acid generated after heat application may change a polarity through a deprotection reaction of the polymer side chain, or the like, and may thus become soluble in an alkaline developer.

For example, the positive polymer resin may be hydrophobic in a state in which no light or heat is applied, and may be soluble in a low-polarity or non-polar developer, but may be changed to hydrophilicity by heat or light, thereby becoming soluble in a polar developer.

The polymer resin may be a novolac resin, and a novolac resin having a weight average molecular weight of 2500 to 15000 based on polystyrene conversion standard may be preferably used.

The novolac resin may be obtained by polycondensing phenol and aldehyde compound under an acid catalyst, and examples of phenol used in this case may include o-cresol, m-cresol, p-cresol, 2,3-xylenol, 2,5-xylenol, 3,4-xylenol, 3,5-xylenol, 2,3,5-trimethylphenol, and 3,4,5-trimethylphenol. Thereamong, o-cresol, m-cresol, p-cresol, 2,3-xylenol, 2,5-xylenol, 3,4-xylenol, 3,5-xylenol and 2,3,5-trimethylphenol are particularly preferred. These phenols may be used alone or in combination of two or more species.

Examples of aldehydes that are polycondensed with phenol may include formaldehyde, trioxane, paraformaldehyde, benzaldehyde, acetaldehyde, propylaldehyde, phenylacetaldehyde, α-phenylpropylaldehyde, β-phenylpropylaldehyde, o-hydroxybenzaldehyde, m-hydroxybenzaldehyde, p-hydroxybenzaldehyde, o-methylbenzaldehyde, m-methylbenzaldehyde, p-methylbenzaldehyde, p-ethylbenzaldehyde, p-n-butylbenzaldehyde, and furfural.

The solubility converting agent may include a photo base generator (PBG) and a thermal acid generator (TAG).

Photo-base generators (PBG) include hydroxides, carboxylates, amines, imines, amides, and mixtures thereof, but the present disclosure is not limited thereto. Specific examples of bases may include ammonium carbonate, ammonium hydroxide, ammonium hydrogen phosphate, ammonium phosphate, tetramethylammonium carbonate, tetramethylammonium hydroxide, tetramethylammonium hydrogen phosphate, tetramethylammonium phosphate, tetraethylammonium carbonate, tetraethylammonium hydroxide, tetraethylammonium hydrogen phosphate, tetraethylammonium phosphate, and combinations thereof. Amines include aliphatic amines, cycloaliphatic amines, aromatic amines, and heterocyclic amines. The amines may be primary, secondary, or tertiary amines. The amines may be monoamines, diamines, or polyamines. Suitable amines may include C1-30 organic amines, imines, or amides, or may be C1-30 quaternary ammonium salts of strong bases (e.g., hydroxides or alkoxides) or weak bases (e.g., carboxylates). Exemplary bases may include amines such as tripropylamine, dodecylamine, tris(2-hydroxypropyl)amine, tetrakis(2-hydroxypropyl)ethylenediamine; aryl amines such as diphenylamine, triphenylamine, aminophenol, and 2-(4-aminophenyl)-2-(4-hydroxyphenyl)propane, hindered amines such as Troger's base, diazabicycloundecene (DBU) or diazabicyclononene (DBN), and amides such as tert-butyl 1,3-dihydroxy-2-(hydroxymethyl)propan-2-ylcarbamate and tert-butyl 4-hydroxypiperidine-1-carboxylate; or ionic quenchers including quaternary alkyl ammonium salts such as tetrabutyl ammonium hydroxide (TBAH) or tetrabutylammonium lactate. Alternatively, the amine may be a hydroxyamine.

The thermal acid generator (TAG) may generate a strong acid capable of deblocking an acid labile polymer protecting group of a photoresist composition in both the unexposed and exposed areas of the photoresist, thereby changing a hydrophobic polymer resin to a hydrophilic one by heat. The thermal acid generator may be hydroxyhexyl paratoluenesulfonate (2-hydroxyethyl p-toluenesulfonate). The thermal acid generator (TAG) may be polymerizable or non-polymerizable, and may be a non-polymerizable thermal acid generator in many applications. Preferred thermal acid generators may have a relatively low molecular weight, and may have, for example, a molecular weight of 3000 or less, more preferably 2500 or less, 2000 or less, 1500 or less, 1000 or less, 800 or less, or even more preferably 500 or less.

The thermal acid generator includes an ionic thermal acid generator, for example, a sulfonate (including a fluorinated sulfonate). The preferred salt may include an ammonium salt. The thermal acid generator may generate an acid having a pKa of less than about 2 (or less than about 1, or less than about 0) upon heat treatment. The pKa of the acid generated by the thermal acid generator may be known or may be determined by conventional methods (e.g., determination of pKa in aqueous solution). In a preferred implementation, the thermal acid generator does not contain an aromatic moiety. In a preferred implementation, the thermal acid generator may include an anionic component having 1 or more carbon atoms.

The preferred thermal acid generator may generate an acid upon heat treatment of a first organic composition. The thermal acid generator may generate an acid upon heat treatment, for example, at a temperature of about 250°C, more preferably at 150°C or 100°C for 60 seconds.

As the solvent, a common solvent may be applied. In other words, the solvent is selected from water, organic solvents, and mixtures thereof. The solvent may include an organic solvent system including one or more organic solvents. The term "organic" means that the solvent system may include at least 50 wt % of a non-polar organic solvent, based on a total solution of the first organic composition. Suitable organic solvents for the first organic composition include, for example, alkyl esters such as alkyl propionates such as n-butyl propionate, n-pentyl propionate, n-hexyl propionate and n-heptyl propionate, and alkyl butyrates such as n-butyl butyrate, isobutyl butyrate and isobutyl isobutyrate; ketones such as 2,5-dimethyl-4-hexanone and 2,6-dimethyl-4-heptanone, aliphatic hydrocarbons such as n-heptane, n-nonane, n-octane, n-decane, 2-methylheptane, 3-methylheptane, 3,3-dimethylhexane and 2,3,4-trimethylpentane, and fluorinated aliphatic hydrocarbons such as perfluoroheptane, alcohols such as straight-chain, branched or cyclic C₄-C₉ monohydric alcohols such as 1-butanol, 2-butanol, isobutyl alcohol, tert-butyl alcohol, 3-methyl-1-butanol, 1-pentanol, 2-pentanol, 4-methyl-2-pentanol, 1-hexanol, 1-heptanol, 1-octanol, 2-hexanol, 2-heptanol, 2-octanol, 3-hexanol, 3-heptanol, 3-octanol and 4-octanol; 2,2,3,3,4,4-hexafluoro-1-butanol, 2,2,3,3,4,4,5,5-octafluoro-1-pentanol and 2,2,3,3,4,4,5,5,6,6-decafluoro-1-hexanol, and C₅-C₉ fluorinated diols such as 2,2,3,3,4,4-hexafluoro-1,5-pentanediol, 2,2,3,3,4,4,5,5-octafluoro-1,6-hexanediol and 2,2,3,3,4,4,5,5,6,6,7,7-dodecafluoro-1,8-octanediol; ethers such as isopentyl ether and dipropylene glycol monomethyl ether; and mixtures containing one or more of these solvents. In one or more example implementations, the solvent may preferably include one or more polar organic solvents.

For example, the first organic composition may include a polar solvent, such as methyl isobutyl carbinol (MIBC). The first organic composition is also a cosolvent and may include aliphatic hydrocarbons, esters, and ethers, such as decane, isobutyl isobutyrate, isoamyl ether, and combinations thereof. The solvent includes the MIBC and the cosolvent. The MIBC may be included in the solvent in an amount ranging from 60% to 99% by volume of the total solvent. Accordingly, the cosolvent may be included in an amount ranging from 1% to 40% by volume of the total solvent.

The solvent may also preferably include one or more nonpolar organic solvents. Suitable nonpolar solvents include, for example, ethers, hydrocarbons, and combinations thereof, and suitable ether solvents may include, for example, alkyl monoethers and aromatic monoethers, and especially solvents having a total carbon number of 6 to 16 may be preferably included. Suitable alkyl monoethers include, for example, 1,4-cineole, 1,8-cineole, pinene oxide, di-n-propyl ether, diisopropyl ether, di-n-butyl ether, di-n-pentyl ether, diisoamyl ether, dihexyl ether, diheptyl ether, and dioctyl ether, and preferably include diisoamyl ether. Suitable aromatic monoethers include, for example, anisole, ethylbenzyl ether, diphenyl ether, dibenzyl ether, and phenetole, and preferably includes anisole. Suitable aliphatic hydrocarbons may include, for example, n-heptane, 2-methylheptane, 3-methylheptane, 3,3-dimethylhexane, 2,3,4-trimethyl pentane, n-octane, n-nonane, n-decane, and fluorinated compounds such as perfluoroheptane. Suitable aromatic hydrocarbons may include, for example, benzene, toluene, and xylene.

As an example, the first organic composition may be manufactured by dissolving a polymer resin in a suitable solvent. For forming the first organic layer ML1 of the present disclosure, the first organic composition may be formed to include 35 wt% of the polymer resin, 60 wt% of the solvent, and 5 wt% of the solubility converting agent, and among the solubility converting agents, the photobase generator may be contained tobe less than the thermal acid generator. For example, the photobase generator may be contained at 1 wt% and the thermal acid generator may be contained at 4 wt%, but the present disclosure is not limited thereto.

The first organic material manufactured in this manner may be applied onto the first upper insulating layer 16 to form a first organic layer ML1.

The formation of the first organic layer ML1 may be performed by coating on the substrate by any suitable means, such as spin-coating, slot-die coating, doctor blading, curtain-coating, roller-coating, spray-coating, dip-coating, or the like. The first organic layer ML1 may be formed by, preferably, spin-coating, and in a typical spin-coating method, the first organic composition may be applied to a substrate 1 that is rotating at a speed of 500 to 4000 revolutions per minute (rpm) for a period of 15 to 90 seconds to obtain a desired layer of a polymer condensed on the substrate 1.

Accordingly, the first organic layer ML1 may be applied onto the upper surface of the first upper insulating layer 16, and may be formed by filling the first openings OP1 along the upper surface.

Referring to FIGS. 2, 3, 4D and 4E, the first organic layer ML1 may be modified to form a vertical sacrificial layer ML1f (S130, S131).

Light may be irradiated onto the first upper insulating layer 16 toward the first organic layer ML1. In this case, while irradiating light onto the first upper insulating layer 16, heat may be applied within the photo process.

As illustrated in FIG. 4D, when both light and heat are injected from an upper portion thereof, an upper first organic layer ML1’ disposed on an upper portion of the first upper insulating layer 16 on which light is incident may generate a base due to the light, and accordingly, the solubility of the upper first organic layer ML1’ may change.

In this case, when heat is injected together, acid may be generated from the thermal acid generator contained in a small amount in the first organic layer ML1, and the bases generated in the first organic layer ML1 may be neutralized. Accordingly, the upper first organic layer ML1’ on the first upper insulating layer 16 has hydrophobicity and thus remains in a state in which the upper first organic layer ML1’ may be dissolved by a low-polarity organic solvent such as nBA.

In this case, since the first organic layer ML1f in the first opening OP1 has no or significantly few bases generated because light is not applied, the first organic layer ML1f in the first opening OP1 is not neutralized and may be acidified by thermal acid generators. Accordingly, the polymer resin have hydrophilicity.

Therefore, among the first organic layers ML1, the upper first organic layer ML1’ on the first upper insulating layer 16 is hydrophobic, and may change to a state in which the solubility in a low-polarity organic solvent such as nBA increases, and the first organic layer ML1f in the first opening OP1 may be transformed into a hydrophilic organic layer, respectively.

Referring to FIGS. 3B and 4E, the upper first organic layer ML1’ having increased solubility on the first upper insulating layer 16 may be removed by cleaning with an acidic solvent (S133).

Accordingly, an upper surface S1 of the first upper insulating layer 16 may be exposed, and the first organic layer ML1f having hydrophilicity may remain as a vertical sacrificial layer ML1f within the first openings OP1 so as to have an upper surface S1 on substantially a similar level to the upper surface S1 of the first upper insulating layer 16.

Accordingly, the planarization may be performed without a separate planarization process, and since a physical chemical process such as chemical mechanical polishing (CMP) may be not required, the circuit elements 20 below may be protected, and the process may be performed within photo equipment like a subsequent photo process, which is economical.

Referring to FIGS. 2 and 4G, a second organic layer ML2 is formed on the exposed first upper insulating layer 16 and light is selectively irradiated to form a pattern (S140).

The second organic layer ML2 is a positive photoresist and, unlike the first organic layer ML1, may not include a thermal acid generator.

For example, the second organic layer ML2 may include a polymer resin similar to the first organic layer ML1, a photo-base generator as a solubility converting agent, and a solvent, and in this case, the content of the solvent may be smaller than that of the first organic layer ML1, but the present disclosure is not limited thereto.

After the second organic layer ML2 is applied to the first upper insulating layer 16 by a predetermined thickness, light may be applied through a photomask PL on which a desired pattern is printed. In this case, a pattern of the light mask PL may be the same as a shape of the first interconnection layer M1 and the first horizontal portion VM1 of the semiconductor device 10 of FIG. 1.

Accordingly, light may be applied all to the second organic layer ML2 covering the first openings OP1, and a portion to which light is applied may be selectively changed into a hydrophilicity by generating a base and may thus be changed to region ML2f having high solubility.

Accordingly, the vertical sacrificial layer ML1f and the first horizontal portion VM1 connected thereto and the region ML2f corresponding to the first wirings ML1 may remain as a hydrophilic organic material.

Referring to FIGS. 2 and 4G, the first organic material ML1f and the second organic material region ML2f having hydrophilicity may be simultaneously removed by cleaning using a polar solvent such as TMAH (S150).

Accordingly, the first upper insulating layer 16 may be etched according to the remaining second organic layer ML2 so that openings OP2 corresponding to the first horizontal portion VM1 and the first vertical portion VV1 may be continuously generated within the first interlayer insulating layer 15 and the first upper insulating layer 16.

As illustrated in FIG. 4G, by removing the remaining patterns of the remaining hydrophobic second organic layer ML2 using a low-polarity solvent such as nBA, the upper surface S1 of the first upper insulating layer 16 may be exposed again.

As illustrated in FIG. 2 and FIG. 4I, by stacking a diffusion barrier 19 within the openings OP2 and burying a conductive layer 18 within the diffusion barrier 19, the first vertical structure VS1 may be formed (S160).

In this manner, when a photo process of forming the openings forming the first horizontal portion VM1 and the first vertical portion VV1 is performed, after forming the opening OP1 forming the lower first vertical portion VV1, an organic layer including both a photo-reactive material and a heat-reactive material is buried in the opening OP1, and a vertical sacrificial layer ML1f filling the corresponding opening may be formed without a separate CMP process by injecting light and heat.

Additionally, the equipment is switched to form a sacrificial structure filling a large opening in a lower width ratio using a separate carbon (C), or the like, and the planarization process of physically applying a strong impact is not performed multiple times, and the lower element may be protected, which is economical.

Next, as in FIG. 1, after the second interlayer insulating layer 25 is stacked to include multiple layers, the continuous vertical structure VS of FIG. 1 may be formed by repeating the same photo process as the first vertical structure VS1.

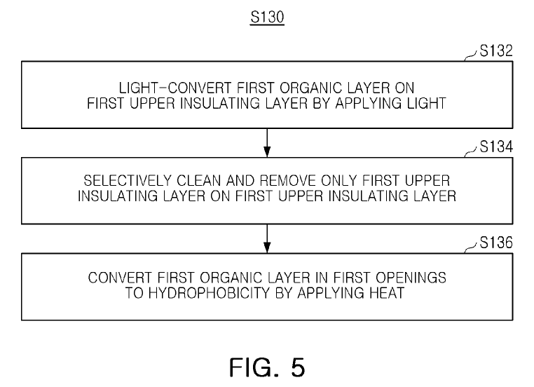

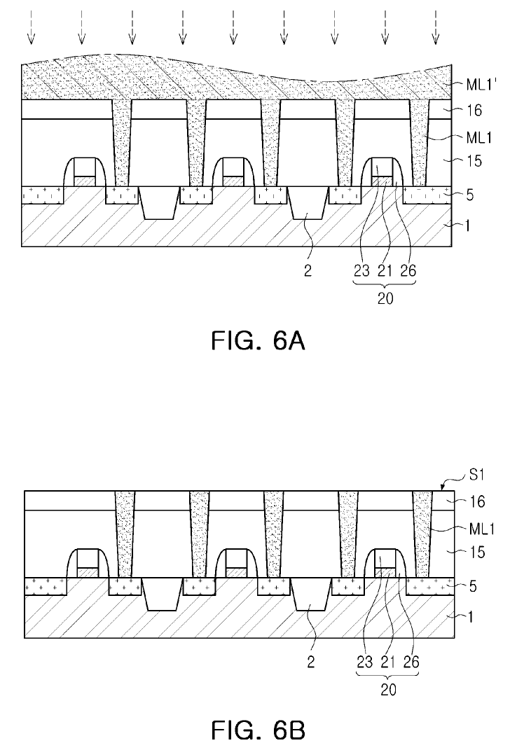

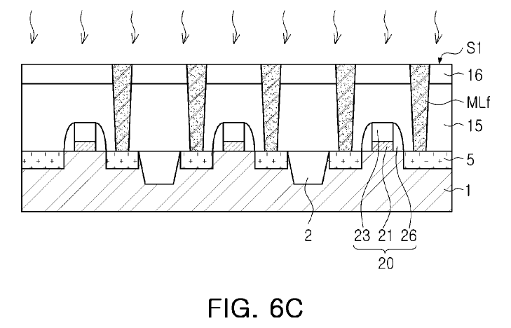

A method of forming a vertical sacrificial layer that fills the first opening OP1 during the formation of such a vertical structure VS may be performed as in FIG. 5, FIG. 6A, FIG. 6B and FIG. 6C.

FIG. 5 is a detailed flow chart for an operation of modifying the first organic layer ML1 of FIG. 2, and FIG. 6A, FIG. 6B and FIG. 6C are schematic cross-sectional views illustrating a method of manufacturing a semiconductor device according to FIG. 5, and are cross-sectional views corresponding to the semiconductor device of FIG. 1.

Referring to FIG. 2, FIG. 5, and FIG. 6A, the first organic layer ML1 applied on the first upper insulating layer 16 and within the first openings OP1 may be converted to form a vertical sacrificial layer.

In this case, the first organic composition for forming the first organic layer may include a positive polymer resin, a solvent, and a solubility converting agent such as a photo acid generator and a thermal acid generator.

The positive polymer resin, the solvent and the thermal acid generator are the same as those described in FIG. 3, and in FIG. 5, a photo acid generator, not a photo-base generator, may be included.

The photo acid generator is obtained by generating an acid by light, and examples thereof may include triphenylsulfonium triflate, triphenylsulfonium antimonate, diphenyliodonium triflate, diphenyliodonium antimonate, methoxydiphenyliodonium triflate, di-t-butyldiphenyliodonium triflate, 2,6-dinitrobenzyl sulfonates, pyrogallol tris(alkylsulfonates), N-hydroxysuccinimide triflate, norbornene-dicarboximide-triflate, triphenylsulfonium nonaflate, diphenyliodonium nonaflate, methoxydiphenyliodonium nonaflate, dit-butyldiphenyliodonium nonaflate, N-hydroxysuccinimide nonaflate, norbornene-dicarboximide-nonaflate, triphenylsulfonium perfluorobutanesulfonate, triphenylsulfonium perfluorooctanesulfonate (PFOS), diphenyliodonium PFOS, methoxydiphenyliodonium PFOS, di-tbutyldiphenyliodoniumtriflate, N-hydroxysuccinimide PFOS, norbornene-dicarboximide PFOS, or combinations thereof, but the present disclosure is not limited thereto.

First, as illustrated in FIG. 5 and FIG. 6A, light may be irradiated toward the first organic layer ML1 on the first upper insulating layer 16 (S132).

When light is applied to the entire surface from an upper portion thereof, the upper first organic layer ML1’ disposed on an upper portion of the first upper insulating layer 16 on which light is incident may generate acid from the photoacid generator due to the light, and accordingly, the solubility of the first organic layer ML1 may change.

Accordingly, the upper first organic layer ML1’ on the first upper insulating layer 16 may change to a hydrophilic state that may be dissolved by a polar organic solvent. In this case, the first organic layer ML1 within the first openings OP1 may not generate acid from the photoacid generator because light is not applied, and may maintain hydrophobicity. Accordingly, the characteristics of the upper first organic layer ML1’ within the first openings OP1 and on the first upper insulating layer 16 may be different from each other, and thus may have different solubilities.

As illustrated in FIG. 5 and FIG. 6B, when the upper first organic layer ML1’ on the first upper insulating layer 16 changes to a state in which the upper first organic layer ML1’ may be dissolved by a polar organic solvent, the upper first organic layer ML1’ may be removed as a polar organic solvent. For example, the upper first organic layer ML1’ having increased solubility on the first upper insulating layer 16 may be removed by cleaning with a basic solvent (S134).

Accordingly, the upper surface S1 of the first upper insulating layer 16 may be exposed, and the hydrophobic first organic layer ML1f may remain as a vertical sacrificial layer within the first openings OP1 so as to have an upper surface on a level substantially similar to that of the upper surface S1 of the first upper insulating layer 16.

Accordingly, the planarization may be performed without a separate planarization process, and since a physical chemical process such as CMP is not required, the circuit elements below may be protected, and the process may be performed within photo equipment like the photo process of the second organic layer ML2 that is performed thereafter, which is economical.

As illustrated in FIGS. 5 and 6c, by applying heat to the semiconductor device 10, acid may be generated from the thermal acid generator within the vertical structure, which is the first organic layer ML1 having hydrophobicity within the first openings OP1, so that the hydrophobic first organic layer ML1f may be changed to hydrophilic (S136). The subsequent process is the same as FIGS. 4F to 4I and will be omitted.

Hereinafter, a semiconductor device is described as a three-dimensional memory device to which a method of forming a vertical sacrificial layer by applying a solubility control process of an organic layer is applied.

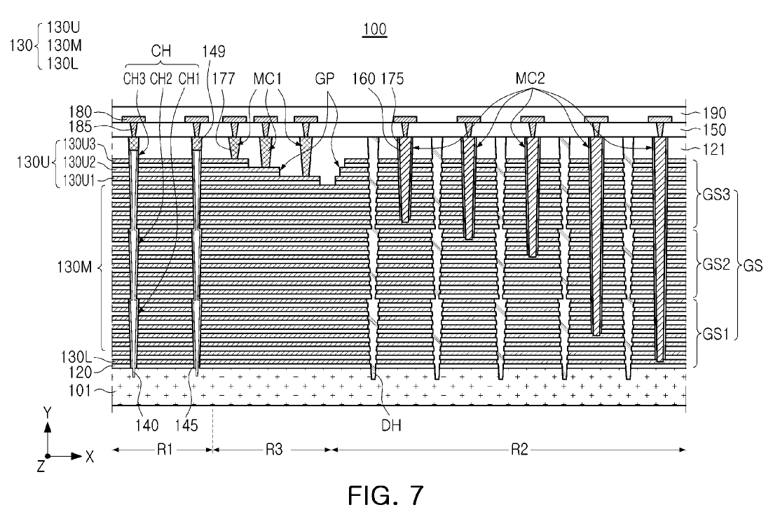

FIG. 7 is a schematic cross-sectional view of a semiconductor device according to an example implementation.

Referring to FIG. 7, a semiconductor device 100 may include a memory region R1 and an extension region R2 on one side of the memory region R1 in the X-direction.

The memory region R1 is a memory cell region in which memory cell strings are disposed, and may be a region in which channel structures CH are disposed. The extension region R2 may correspond to a region for electrically connecting the channel structures CH to peripheral circuit structures, and may be a region in which a plurality of word line contact plugs MC2 connected to gate electrodes 130 on different levels are disposed, but the present disclosure is not limited thereto. The memory region R1 may be defined as each mat when a plurality of mats MAT are disposed, but the present disclosure is not limited thereto.

A string selection region R3 may be disposed between the memory region R1 and the extension region R2. The string selection region R3 may be defined as a region in which string selection contact plugs MC1 for selecting each of the gate electrodes 130, which are string selection lines, are disposed.

The semiconductor device 100 may have a structure in which the memory region R1, the string selection region R3, and the extension region R2 are disposed in succession in the X-direction. Depending on the separation of the gate electrodes 130, the memory region R1 and the string selection region R3 may be defined as a first region, and the extension region R2 may be defined as a second region.

The semiconductor device 100 may include a conductive layer 101 within a memory region R1, a string selection region R3 and an extension region R2, stack structures (GS: GS1 to GSk where k is 1, 2, ..., a positive integer) in which gate electrodes 130 and interlayer insulating layers 120 are alternately stacked on an upper surface of the conductive layer 101, channel structures CH disposed in the memory region R1 so as to penetrate through the stack structures GS1 to GSk, separation regions MS extending in the X-direction by penetrating through the stack structures GS1 to GSk, and insulating regions SS penetrating through a portion of the gate electrodes 130. A interconnection structure and a passivation layer may be further included in a lower portion of the conductive layer 101.

Support structures DH and word line contact plugs MC2 may be disposed within the extension region R2, and the support structures DH and string selection contact plugs MC1 may be disposed in the string selection region R3.

In FIG. 7, the contact plugs MC1 and MC2 are illustrated as extending by different lengths for connection between each gate electrode 130 and the contact plugs MC1 and MC2, but the present disclosure is not limited thereto.

The memory region R1 and the extension region R2 may include a cell region insulating layer 150 in an upper portion of the stack structure GS1 to GSk, and may include studs 185 penetrating through the cell region insulating layer 150, and performing electrical connection with the channel structure CH and the contact plugs MC1 and MC2, and an upper interconnection structure 180 in an upper portion of the cell region insulating layer 150.

The conductive layer 101 is a common source line, and may include at least one of a conductive material such as doped silicon or a conductive material such as a metal or a metal nitride. For example, the conductive layer 101 may include a silicon layer having an N-type conductivity that may be a common source.

The gate electrodes 130 may be vertically spaced apart from each other and stacked on the upper surface of the conductive layer 101 to form a stack structure (GS: GS1-GS3) together with the interlayer insulating layers 120. The gate electrodes 130 may extend from the extension region R2 to the memory region R1 on one side thereof, but upper gate electrodes 130U may be physically and electrically separated between the string selection region R3 and the extension region R2.

The stack structure GS1 to GSk may include a plurality of stack structures GS1 to GSk vertically stacked.

A lower stack structure disposed on the upper surface of the conductive layer 101 may be referred to as a first stack structure GS1, the stack structures GS2 to GSk on the first stack structure GS1 may be sequentially referred to as a second stack structure GS2 and a third stack structure GS3, respectively, and the second to third stack structures GS2 and GS3 may be referred to as the upper stack structure. Additionally, the kth stack structure (GSk, k=3) disposed in an uppermost portion and furthest from the conductive layer 101 in the Z-direction may be referred to as an uppermost stack structure.

Within the stack structures GS1 to GSk, gate electrodes 130 and interlayer insulating layers 120 may be alternately stacked in the Z-direction, and an interface S between the stack structures GS1 to GSk may be defined as an interface between an uppermost gate electrode 130 of the stack structures GS1 and GS2 disposed in a lower portion thereof and a lowermost interlayer insulating layer 120 of the stack structures GS2 and GS3 disposed in an upper portion. A thickness of the lowermost interlayer insulating layer 120 and the uppermost gate electrode 130 disposed at the interface may be substantially the same as a thickness of the other interlayer insulating layers 120 and the gate electrode 130. A length of each of the stack structures GS1 to GS3 in the Z-direction and the number of gate electrodes 130 may be substantially the same, but the present disclosure is not limited thereto.

For the entire stack structures GS1 to GS3, the gate electrodes 130 may include at least one lower gate electrode 130L included in a gate of a ground selection transistor, memory gate electrodes 130M included in a plurality of memory cells, and upper gate electrodes 130U as a string selection line included in gates of string selection transistors. Here, the lower gate electrode 130L and the upper gate electrodes 130U may be referred to as “lower” and “upper” based on a direction during the manufacturing process. The number of memory gate electrodes 130M of memory cells may be determined according to the capacity of the semiconductor device 100. According to an example implementation, the number of upper and lower gate electrodes 130U and 130L may be 1, 2, or more, respectively, and may have a structure identical to or different from the memory gate electrodes 130M. In an example implementation, the number of upper gate electrodes 130U may be illustrated as being three. The erase gate electrodes 130 may be further disposed below the upper gate electrodes 130U. Additionally, some of the gate electrodes 130, for example, the memory gate electrodes 130M adjacent to the upper or lower gate electrodes 130U and 130L, may be dummy gate electrodes 130, but the present disclosure is not limited thereto.

The gate electrodes 130 may be disposed to be separated from each other in the Y-direction by separation regions extending continuously from the memory region R1 to the extension region R2. The gate electrodes 130 between a pair of separation regions MS may form one memory block BLK, but the range of the memory block BLK is not limited thereto. Some of the gate electrodes 130, for example, the memory gate electrodes 130M, may form one layer each within one memory block BLK.

The gate electrodes 130 may be vertically spaced apart from each other and stacked within the memory region R1, the string selection region R3, and the extension region R2, and may maintain a continuous plate shape without forming a stepwise-shaped stepped structure even within the extension region R2. A contact region of each gate electrode 130 may be defined as a region in contact with the contact plugs MC1 and MC2 within the string selection region R3 and the extension region R2.

The gate electrodes 130 may be formed of, for example, W, Ru, Mo, Nb, Ni, Co, Ti, Ta, TiN, TaN, WN, NbN, TiAl, TiAlN, TiSi, TiSiN, TaSi, TaSiN, RuTiN, NiSi, CoSi, or combinations thereof, but the present disclosure is not limited thereto. According to example implementations, the gate electrodes 130 may further include a diffusion barrier, and for example, the diffusion barrier may include tungsten nitride (WN), tantalum nitride (TaN), titanium nitride (TiN), or combinations thereof.

The interlayer insulating layers 120 may be disposed between the gate electrodes 130 to form stack structures GS1, GS2 and GS3. The interlayer insulating layers 120 may also be spaced apart from each other in a direction, perpendicular to an upper surface of the conductive layer 101 and may extend in the X-direction, similarly to the gate electrodes 130. The interlayer insulating layers 120 may include an insulating material such as silicon oxide or silicon nitride.

In example implementations, thicknesses of the interlayer insulating layers 120 are generally the same, but some thicknesses may not be the same. For example, an uppermost interlayer insulating layer 121, among the interlayer insulating layers 120, may have a greater thickness than the other interlayer insulating layers 120, but the present disclosure is not limited thereto.

Upper gate electrodes 130U1 to 130U3 may be separated into a plurality of sub-regions in the Y-direction within the memory region R1 and the string selection region R3, and may form a single plate shape without being separated from each other within the extension region R2. In this case, insulating regions SS1 and SS2 selectively may penetrate through only the upper gate electrodes 130U1 to 130U3 and may not extend below the memory gate electrode 130M, so that the memory gate electrodes 130M and the lower gate electrodes 130L may not be separated from each other by the insulating regions SS1 and SS2, and the memory region R1, the string selection region R3 and the extension region R2 may all be stacked in a single plate shape, respectively.

The channel structures CH may be spaced apart from each other in rows and columns on the conductive layer 101 of the memory region R1. In the memory region R1, the channel structures CH may be disposed in a zigzag shape in one direction in an X-Y plane. The channel structures CH may penetrate through the gate electrodes 130, and may extend in a vertical direction, perpendicular to the upper surface of the conductive layer 101, for example, in the Z-direction, and may have a pillar shape and an inclined side surface in which a width thereof becomes narrower toward the conductive layer 101 depending on an aspect ratio.

Each of the channel structures CH may have a form in which k channel portions (CH1 to CHk where k is 1, 2, …, a positive integer) penetrating through k stack structures GS1 to GSk of the gate electrodes 130 are connected, and in an example implementation, three first to third channel portions CH1 to CH3 penetrating through three stack structures GS1 to GS3 may be connected to each other. A bending portion may be provided due to a difference or change in width in a connection portion between the first to third channel portions CH1 to CH3.

Each of the channel structures CH may include a first portion within the stack structures GS1 to GS3 and a second portion protruding below the stack structures GS1 to GS3 and coming into contact with the conductive layer 101.

A channel layer 140 may be disposed entirely in the first and second portions of the channel structures CH, and may be disposed up to an upper end of the second portion. The channel layer 140 may include a protrusion portion protruding and exposed below the stack structures GS1 to GS3 disposed in a second portion of the channel structures CH, and a non-protrusion portion disposed in the first portion of the channel structure CH. Protrusion lengths of the second portions of the channel structures CH and the protrusion portions of the channel layer 140 may not be the same, but the present disclosure is not limited thereto. The channel layer 140 may be formed in an annular shape in which a side surface thereof surrounds a buried insulating layer inside, but may also have a columnar shape such as a cylindrical or prismatic column without a buried insulating layer according to an example implementation. The protrusion portion of the channel layer 140 may extend into the conductive layer 101 and may directly contact the conductive layer 101. The protrusion portion may be formed to have a gentle inclination with the non-protrusion portion so that the annular shape is maintained. The channel layer 140 may include a semiconductor material such as polycrystalline silicon or single crystal silicon, and the semiconductor material may be an undoped material or a material including a P-type or N-type impurity.

In the channel structures CH, channel pads 149 may be disposed in an upper portion of the channel layer 140. The channel pads 149 may be disposed to cover an upper surface of the buried insulating layer and may be electrically connected to the channel layer 140. The channel pads 149 may include, for example, doped polycrystalline silicon.

A channel dielectric layer 145 may be disposed between the gate electrodes 130 and the channel layer 140. The channel dielectric layer 145 may include a tunneling layer, a charge storage layer and a blocking layer sequentially stacked from the channel layer 140. The tunneling layer may tunnel charges into the charge storage layer, and may include, for example, silicon oxide (SiO₂), silicon nitride (Si₃N₄), silicon oxynitride (SiON), or combinations thereof. The charge storage layer may be a charge trap layer or a floating gate conductive layer. The blocking layer may include silicon oxide (SiO₂), silicon nitride (Si₃N₄), silicon oxynitride (SiON), a high-κ dielectric material, or combinations thereof. According to example implementations, at least a portion of the channel dielectric layer 145 may form a channel dielectric layer extending horizontally along the gate electrodes 130.

The channel dielectric layer 145 may be removed from a portion below the stack structures GS1 to GS3 so that a protrusion portion of the channel layer 140 is exposed to the outside in the second portion. Accordingly, a lower end of the channel dielectric layer 145 may be in contact with the conductive layer 101, and a side surface of the channel dielectric layer 145 in the first portion may be disposed to surround the non-protrusion portion of the channel layer 140.

The channel layer 140, the channel dielectric layer 145 and the buried insulating layer may be connected to each other between the first to third channel portions CH1 to CH3.

The support structures DH may be disposed in the string selection region R3 and the extension region R2, and may have the structure identical to or similar to that of the channel structures CH, but may not perform an actual function in the semiconductor device 100. The support structures DH may be disposed in rows and columns in the string selection region R3 and the extension region R2. The support structures DH have a diameter equal to or larger than a maximum diameter of the channel structures CH, and may have a diameter equal to or smaller than a maximum diameter of the contact plugs MC1 and MC2. The shape, number, and/or gap of the support structures DH may be different. The channel structures CH and the support structures DH may have a circular or nearly circular shape, but are not limited thereto and may have an oval shape. The support structures DH may include vertical portions penetrating through the stack structures GS1 to GS3 like the channel structures CH, and extending in the Y-direction, and horizontal portions protruding from the vertical portions toward each gate electrode 130, but the shape of the support structures DH is not limited thereto. The support structures DH may also have a structure including a plurality of bent portions corresponding to bent portions of the first to third channel portions CH1 to CH3 of the channel structure CH. The support structures DH may be supporters that may prevent deformation such as warpage of the stack structures GS1 to GS3.

The upper gate electrodes 130U may include a contact region for contacting the first and second string selection contact plugs MC1 in the string selection region R3, and may include a stepwise-shaped stepped structure GP so that the corresponding contact area is exposed to the outside.

When three upper gate electrodes 130U1 to 130U3 are assigned to a string selection line, the three upper gate electrodes 130U1 to 130U3 may have a stepwise-shaped stepped structure in which a length thereof increases toward a lower portion. Accordingly, a stepwise-shaped dummy stepped structure GP may be formed in the extension region R2 on an opposite side thereof, but a stepwise width of the dummy stepped structure GP of the extension region R2 and a stepwise width of the stepped structure GP of the string selection region R3 may be different from each other. For example, the stepwise width of the dummy stepped structure GP of the extension region R2 may be narrower than the stepwise width of the stepped structure GP of the string selection region R3, but the present disclosure is not limited thereto. The string selection contact plugs MC1 may be disposed to contact the contact region of each string selection line exposed according to the stepwise-shaped stepped structure GP.

The string selection contact plugs MC1 may be formed only with a conductive layer 177 in the same manner. For example, only the conductive layer 177 may be disposed in a plug shape without a separate side insulating layer and may be disposed to contact an upper surface of the contact region of the exposed upper gate electrode 130U, respectively. In this case, a contact barrier layer surrounding the conductive layer may be further disposed to surround the conductive layer 177, but the present disclosure is not limited thereto.

A stepwise-shaped stepped structure GP may be formed between the string selection region R3 and the extension region R2, thus cutting the upper gate electrodes 130U1 to 130U3.

The word line contact plugs MC2 connected to the gate electrodes 130 in the extension region R2 may be included. The word line contact plugs MC2 may penetrate through at least a portion of the uppermost interlayer insulating layer 121 and may extend downwardly in the Z-direction and may thus be connected to upper surfaces of allocated gate electrodes 130. The word line contact plugs MC2 may have a circular or oval shape on the X-Y plane and may be disposed to be spaced apart from each other in the X-direction and the Y-direction.

Each of the word line contact plugs MC2 includes a plug conductive layer 175 and a contact barrier surrounding a side surface and a lower surface of the plug conductive layer 175, and a side insulating layer 160 may be further disposed on a side surface of the contact barrier of the word line contact plugs MC2. The word line contact plugs MC2 and the side insulating layer 160 thereof may be referred to as a contact structure.

In each of the word line contact plugs MC2, a lower surface of the contact barrier layer may be connected to and in contact with a contact region of one of the gate electrodes 130, and the side insulating layer 160 may electrically insulate the gate electrodes 130 adjacent to a side surface of the plug conductive layer 175 from the plug conductive layer 175. The plug conductive layer 175 may extend continuously from lower surfaces of the word line contact plugs MC2 in contact with a contact region of the gate electrode 130 to upper surfaces of the word line contact plugs MC2.

In an example implementation, each stage of the stack structures GS1 to GS3 may include eight gate electrodes 130, and at least one word line contact plug MC2 in physical/electrical contact with each gate electrode 130 may be disposed therein. The number of gate electrodes 130 in the first to third stack structures GS1 to GS3 is an example and the present disclosure is not limited thereto.

In the extension region R2, when word line contact plugs MC2 respectively connected to the memory gate electrodes 130M and the lower gate electrodes 130L are allocated one by one, the word line contact plugs MC2 may be disposed with different lengths so as to be connected to gate electrodes 130M and 130L on different levels.

The first to third stack structures GS1 to GS3 are illustrated as including eight stages of gate electrodes 130, and since the three upper gate electrodes 130U function as string selection lines, 21 gate electrodes 130M and 130L may remain. Word line contact plugs MC2 whose lengths are adjusted differently so as to contact upper surfaces of 21 gate electrodes 130M and 130L respectively may be disposed within the extension region R2.

An arrangement of the word line contact plugs MC2 may be disposed in various manners, and in an example implementation, it is illustrated that the word line contact plugs MC2 may be disposed so as to contact the allocated gate electrodes 130 respectively since the word line contact plugs MC2 become longer in the Z-direction as they go in the X-direction in one column. Accordingly, as illustrated in FIG. 7, the word line contact plugs MC2 disposed in the X-direction may be exemplified as contacting the eighth, tenth, twelfth, twenty-first and twenty-fourth gate electrodes 130 when the uppermost gate electrode 130 is referred to as a first gate electrode 130U3.

In the word line contact plugs MC2, the side insulating layer 160 may be disposed only on a side surface of the word line contact plugs MC2 so that a lower gate electrode 130 and a lower surface of the contact barrier layer are in direct contact with each other, and according to an example implementation, some of the word line contact plugs MC2 may be disposed to extend to a level lower than that of an upper surface of the assigned gate electrode 130, but do not extend to a level lower than that of a lower surface of the allocated gate electrode 130. Accordingly, a lower surface of the word line contact plugs MC2 may be the same as or lower than an upper surface of the gate electrode 130 with which the lower surface thereof is in contact, and may be disposed on a level higher than that of a lower surface of the gate electrode 130.

The plug conductive layer 175 of the word line contact plugs MC2 may include a conductive material, for example, at least one of tungsten (W), copper (Cu), aluminum (Al), and alloys thereof. For example, the plug conductive layer 175 may include tungsten (W). The contact barrier layer may include tungsten nitride (WN), tantalum nitride (TaN), titanium nitride (TiN), or combinations thereof.

The side insulating layers 160 may include an insulating material, for example, silicon oxide, silicon nitride, or silicon oxynitride.

Upper surfaces of the word line contact plugs MC2 may be wider than widths of lower surfaces of each word line contact plug MC2, and the word line contact plugs MC2 may have inclined side surfaces accordingly.

In the string selection region R3 and the extension region R2, the support structures DH may be arranged to have a regular pattern around the word line contact plugs MC2. For example, the support structures DH and the word line contact plugs MC2 may be disposed alternately, but the present disclosure is not limited thereto.

The cell region insulating layer 150 may be disposed to cover a stack structure GS. The cell region insulating layer 150 may include a plurality of insulating layers according to example implementations. The cell region insulating layer 150 may be formed of an insulating material, and may include, for example, at least one of silicon oxide, silicon nitride, and silicon oxynitride.

The studs 185 and the cell interconnection lines 180 may form a cell interconnection structure electrically connected to the memory cells. The studs 185 may penetrate through a portion of the cell region insulating layer 150 and may be connected to the channel structures CH and the contact structures MC1 and MC2, and may be electrically connected to the channel layers 140 and the gate electrodes 130. The studs 185 may have a plug shape, and the cell interconnection lines 180 may have a line shape, but the present disclosure is not limited thereto. The studs 185 and the cell interconnection lines 180 may include metal, and may include, for example, tungsten (W), copper (Cu) and aluminum (Al).

An upper insulating layer 190 may be further disposed to cover the cell interconnection lines 180 above the cell region insulating layer 150. The upper insulating layer 190 may be formed of an insulating material, and may include, for example, at least one of SiO, SiN, SiCN, SiOC, SiON or SiOCN.

Hereinafter, a method of manufacturing a semiconductor device 100 of FIG. 7 by forming a vertical sacrificial layer by applying an organic layer having controlled solubility will be described.

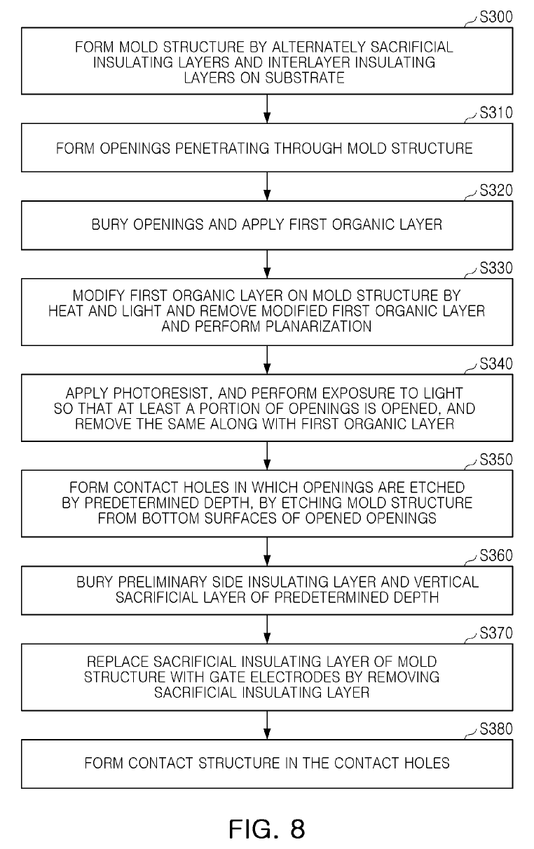

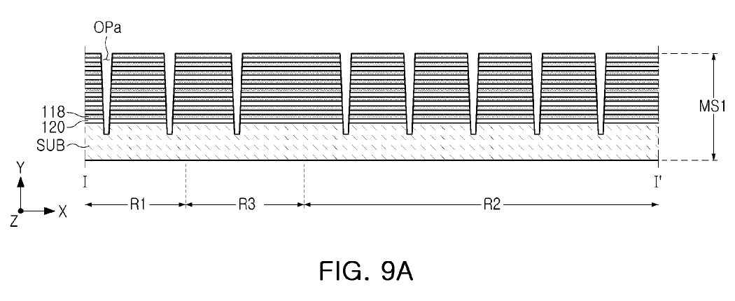

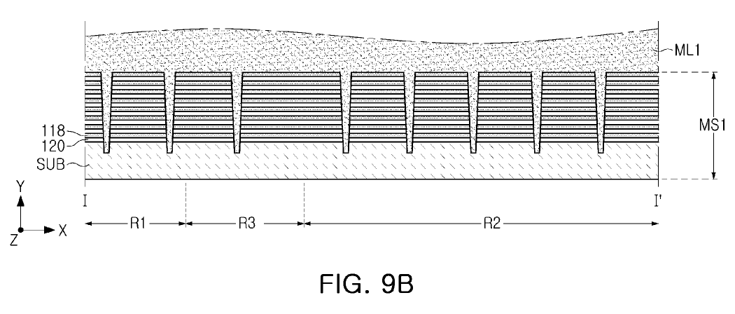

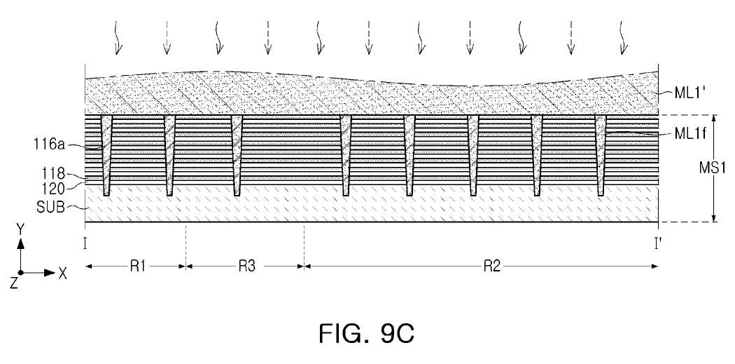

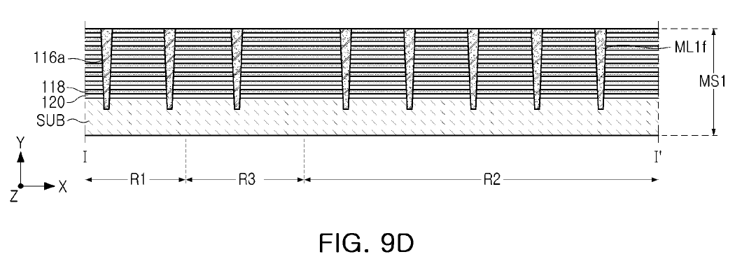

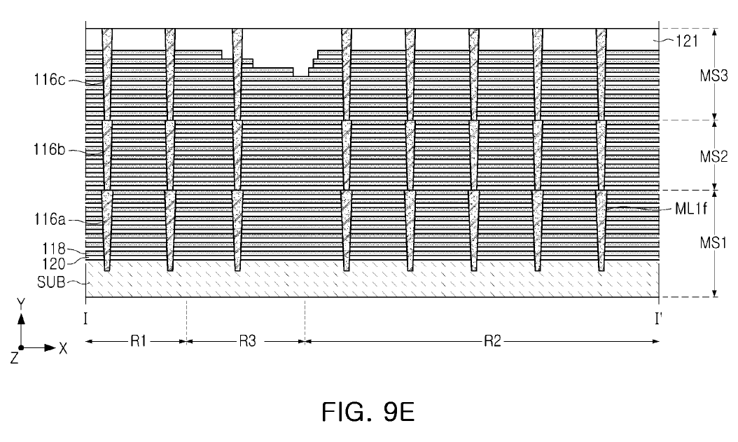

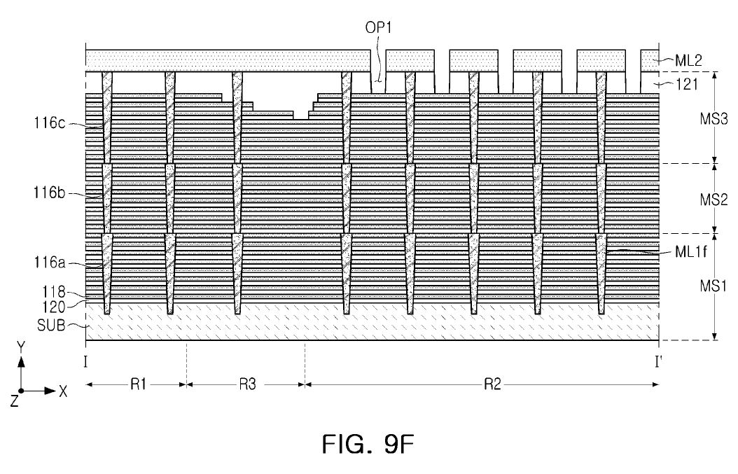

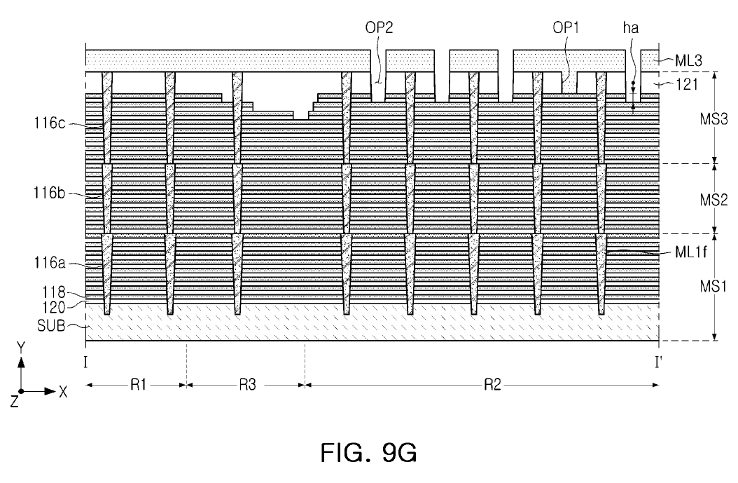

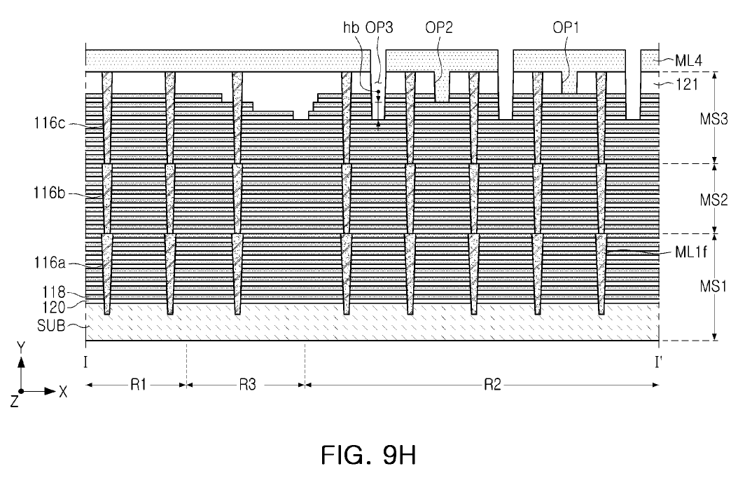

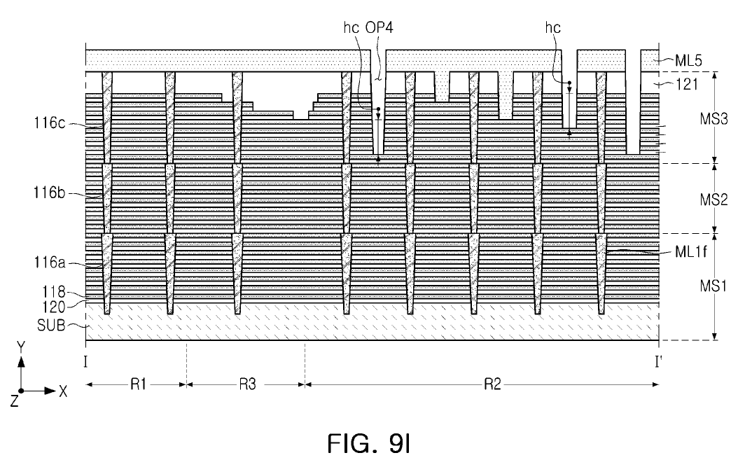

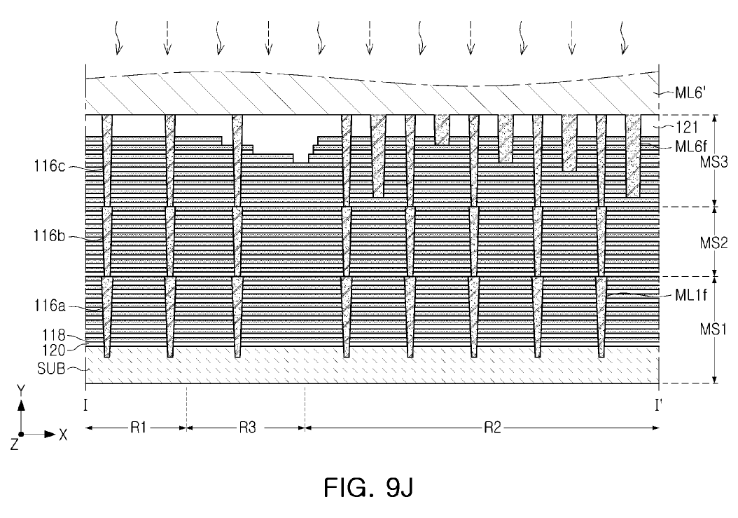

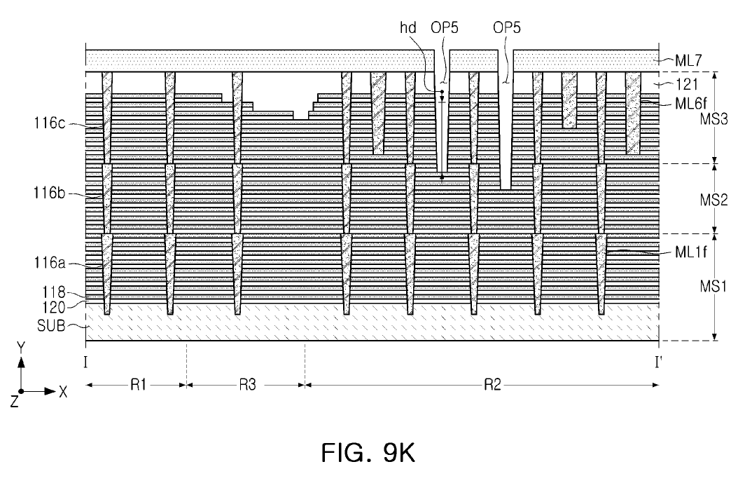

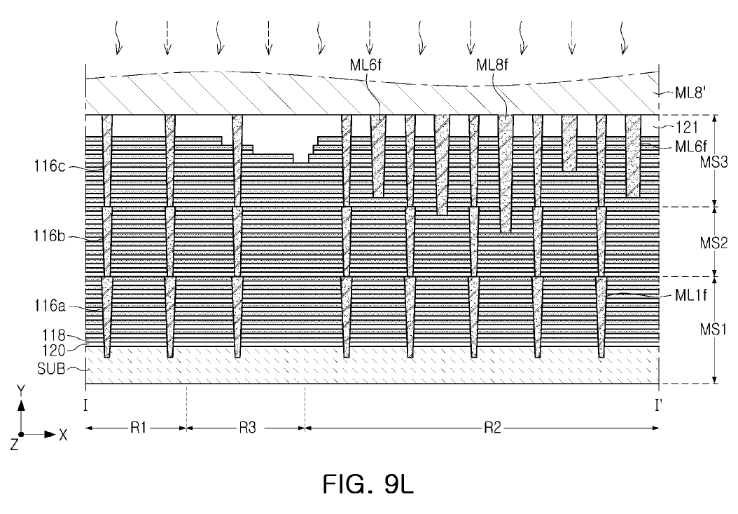

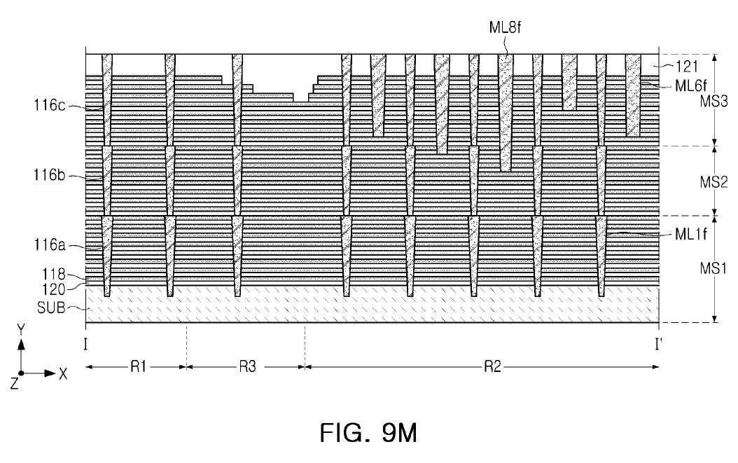

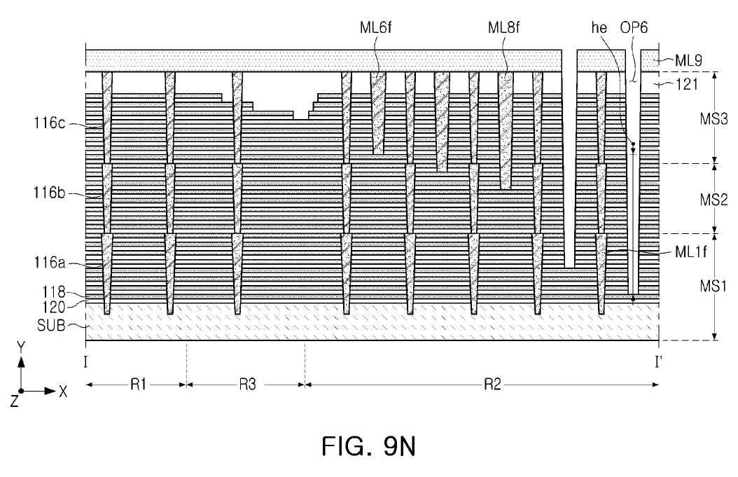

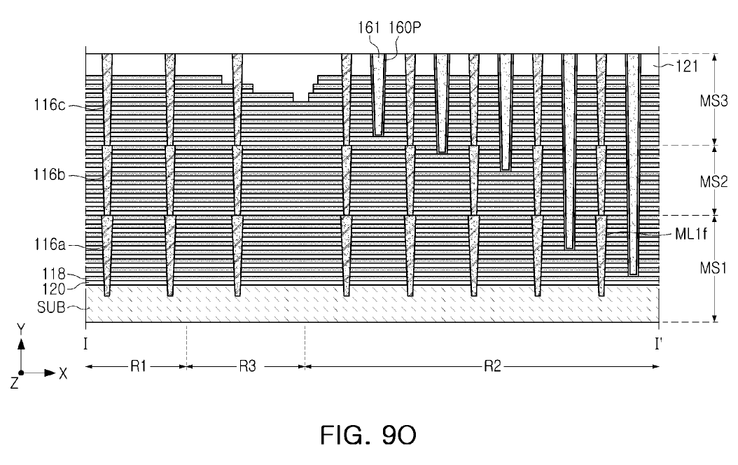

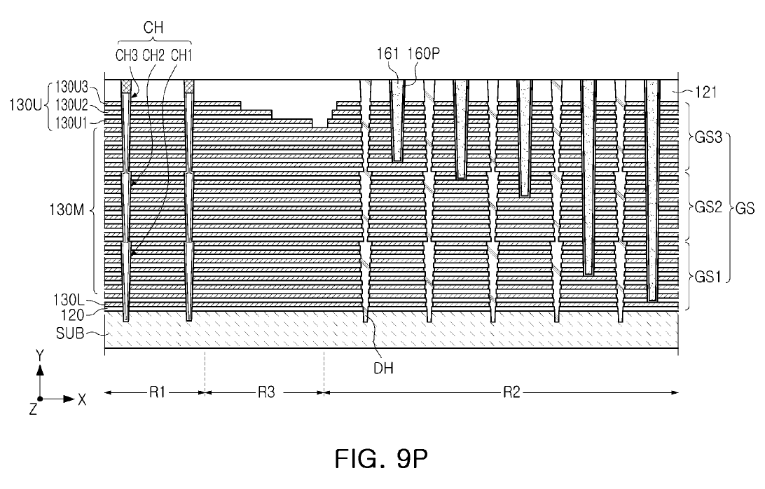

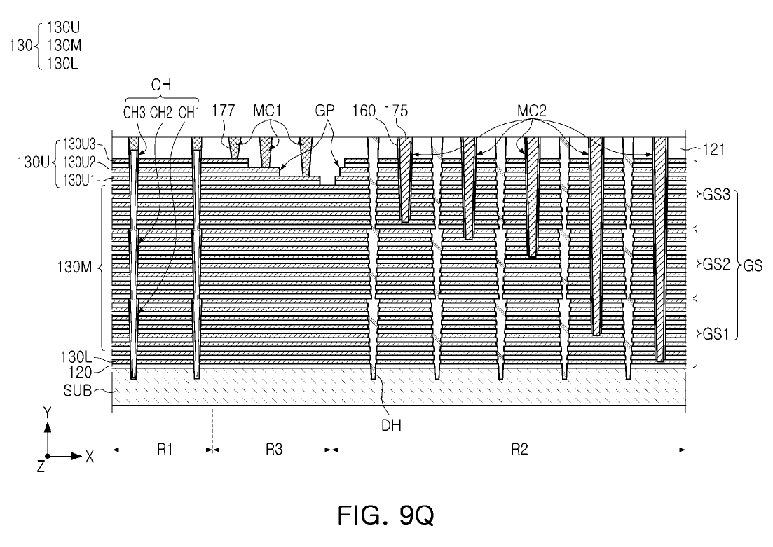

FIG. 8 is a flowchart explaining a method of manufacturing the semiconductor device of FIG. 7, and FIGS. 9A - 9Q are schematic cross-sectional views illustrating a method of manufacturing the semiconductor device of FIG. 8.

Referring to FIG. 8 and FIG. 9A, sacrificial insulating layers 118 and interlayer insulating layers 120 are alternately stacked on a base substrate SUB (S300), and vertical holes OPa may be formed.

The base substrate SUB is a layer removed through a subsequent process, and may be a semiconductor substrate such as a silicon (Si) wafer. A first mold structure MS1 is primarily formed, and then HARC etching penetrating through the first mold structure MS1 is performed to form vertical holes OPa.

The sacrificial insulating layers 118 may be layers replaced with gate electrodes 130 (see FIG. 7) through a subsequent process. The sacrificial insulating layers 118 may be formed of a different material from the interlayer insulating layers 120, and may be formed of a material that may be etched with etch selectivity under specific etching conditions with respect to the interlayer insulating layers 120. For example, the interlayer insulating layer 120 may be formed of at least one of silicon oxide or silicon nitride, and the sacrificial insulating layers 118 may be formed of a different material from the interlayer insulating layer 120 selected from silicon, silicon oxide, silicon carbide and silicon nitride.

The vertical holes OPa may be formed in positions corresponding to the channel structures CH and the support structures DH of FIG. 7. The vertical holes OPa may be formed, for example, to have the same size as the channel structures CH and the support structures DH.

Referring to FIG. 9B, a first organic layer ML1 may be applied onto an upper surface of the first mold structure to fill the vertical holes OPa.

A first organic layer ML1 may be prepared, and the first organic layer ML1 may be applied onto the first mold structure ML1 to fill the vertical holes OPa.

The first organic layer ML1 is a photoresist organic layer, and may include a positive polymer resin, a photo-base generator as a solubility converting agent, a thermal acid generator, and a solvent.

The positive polymer resin may be decomposed under the action of a base, thereby increasing the solubility of the photoresist in an acidic developer. The positive polymer resin is insoluble or poorly soluble in an acidic developer, but the base generated after light irradiation may change the polarity by a deprotection reaction of a polymer side chain, or the like, so that the positive polymer resin may become soluble in an acidic developer.

The polymer resin is a novolac resin and may preferably use a novolac resin having a weight average molecular weight of 2500 to 15000 in terms of polystyrene conversion. Examples of the polymer resin are as described above.

As a solubility converting agent such as a photo-base generator (PBG) and a thermal acid generator (TAG), the photo-base generator includes a hydroxide, a carboxylate, an amine, an imine, an amide, and mixtures thereof, but the present disclosure is not limited thereto. Specific examples of the base include ammonium carbonate, ammonium hydroxide, ammonium hydrogen phosphate, ammonium phosphate, tetramethyl ammonium carbonate, tetramethyl ammonium hydroxide, tetramethyl ammonium hydrogen phosphate, tetramethyl ammonium phosphate, tetraethyl ammonium carbonate, tetraethyl ammonium hydroxide, tetraethyl ammonium hydrogen phosphate, tetraethyl ammonium phosphate, and combinations thereof. Amines include aliphatic amines, cycloaliphatic amines, aromatic amines, and heterocyclic amines. The amines may be primary, secondary or tertiary amines. The amines may be monoamines, diamines, or polyamines. Suitable amines may include C1-30 organic amines, imines, or amides, or may be C1-30 quaternary ammonium salts of strong bases (e.g., hydroxides or alkoxides) or weak bases (e.g., carboxylates). Exemplary bases include amines such as tripropylamine, dodecylamine, tris(2-hydroxypropyl)amine, tetrakis(2-hydroxypropyl)ethylenediamine; aryl amines such as diphenylamine, triphenylamine, aminophenol, and 2-(4-aminophenyl)-2-(4-hydroxyphenyl)propane, hindered amines such as Troger base, diazabicycloundecene (DBU) or diazabicyclononene (DBN), and amides such as tert-butyl 1,3-dihydroxy-2-(hydroxymethyl)propan-2-ylcarbamate and tert-butyl 4-hydroxypiperidine-1-carboxylate; or ionic quenchers including quaternary alkyl ammonium salts such as tetrabutyl ammonium hydroxide (TBAH) or tetrabutylammonium lactate.

The thermal acid generator may generate a strong acid capable of deblocking the acid labile polymer protective group of the first organic composition in both the unexposed and exposed regions of the photoresist, thereby changing the hydrophobic polymer resin into a hydrophilic one by heat. The thermal acid generator may be hydroxyhexyl paratoluenesulfonate (2-hydroxyethyl p-toluenesulfonate). The thermal acid generator (TAG) may be polymerizable or non-polymerizable. Examples of the thermal acid generator (TAG) are as described above.

The solvent may be a general solvent. For example, the solvent is selected from water, an organic solvent, and mixtures thereof. The solvent may include an organic solvent system including one or more organic solvents. The solvent may include a polar solvent such as methyl isobutyl carbinol (MIBC). The solubility-converting agent may also include aliphatic hydrocarbons, esters, and ethers, such as decane, isobutyl isobutyrate, isoamyl ether, and combinations thereof, as cosolvents. The solvent may include MIBC and a cosolvent.

As an example, the first organic composition may be prepared by dissolving a polymer resin in a suitable solvent. The polymer resin of the present disclosure is typically used in an amount sufficient to provide an exposed coating layer of a developable resist, such as an aqueous acidic solution. For forming the first organic layer ML1, the first organic composition may be formed to include 35 wt % of the polymer resin, 60 wt % of the solvent, and 5 wt % of the solubility-converting agent, and among the solubility-converting agents, the photobase generator may be contained in an amount less than that of the thermal acid generator. For example, the photobase generator may be contained at 1 wt % and the thermal acid generator may be contained at 4 wt %, but the present disclosure is not limited thereto.

The first organic composition manufactured in this manner may be applied onto an upper surface of the first mold structure MS1 as illustrated in FIG. 9B to form a first organic layer ML1.

The formation of the first organic layer ML1 may be coated onto the substrate by any suitable means, such as spin-coating, slot-die coating, doctor blading, curtain-coating, roller-coating, spray-coating, dip-coating, or the like. Preferably, the first organic layer ML1 may be formed by spin-coating, and in a typical spin-coating method, the composition is applied to the first mold structure MS1 which rotates at a speed of 500 to 4000 rpm (rotations per minute) for a period of 15 to 90 seconds to obtain a desired layer of a polymer condensed on the first mold structure MS1. Accordingly, the first organic composition may be applied onto the upper surface of the first mold structure MS1, and thus may be formed to fill the vertical holes OPa.

Referring to FIG. 9C , the first organic layer ML1 may be converted to form a first vertical sacrificial layer 116a.

Light may be irradiated toward the first organic layer ML1 onto the upper surface of the first mold structure MS1. In this case, while irradiating the light onto the upper surface of the first mold structure MS1, heat may be applied within the photo process.

As illustrated in FIG. 9C, when both light and heat are injected from an upper portion, the first organic layer ML1 disposed on the upper surface of the first mold structure MS1 on which the light is incident generates a base by the light, and accordingly, the solubility of the first organic layer ML1 may change.

In this case, when heat is injected together, acid may be generated from the thermal acid generator contained in a small amount in the first organic layer ML1’, and the bases generated in the first organic layer ML1 may be neutralized. Accordingly, the first organic layer ML1’ on the upper surface of the first mold structure MS1 remains hydrophobic and may be dissolved by a low-polarity organic solvent such as nBA.

In this case, since light is not applied to the first organic layer ML1f in the vertical hole OPa and there are no or only a very small number of bases generated, the first organic layer ML1f in the vertical hole OPa may not be neutralized, and may be acidified by the thermal acid generators. Accordingly, the polymer resin may have hydrophilicity.

Accordingly, among the first organic layer ML1f, the first organic layer ML1’ on the upper surface of the first mold structure MS1 may be changed to a hydrophobic state and has increased solubility in low-polarity organic solvents such as nBA, and the first organic layer ML1f in the vertical hole OPa may be changed to a hydrophilic state.

Referring to FIG. 9D, the first organic layer ML1’ having increased solubility on the upper surface of the first mold structure MS1 may be removed by cleaning with a nonpolar solvent.

Accordingly, the upper surface of the first mold structure MS1 may be exposed, and the first organic layers ML1f having hydrophilicity may remain as the first vertical sacrificial layer 116a in the vertical holes OPa so as to have an upper surface on a substantially similar level to the upper surface of the first mold structure MS1.

Accordingly, the planarization may be performed without a separate planarization process, and since a physical chemical process such as CMP is not required, the circuit elements below may be protected, and the process may be performed within photo equipment like the subsequent photo process, which is economical.

As illustrated in FIG. 9E, the process of FIG. 9A, FIG. 9B, FIG. 9C and FIG. 9D may be repeated to perform stacking up to the third mold structure MS1, and the second and third vertical sacrificial layers penetrating through each stack structure MS1 may be formed, respectively.

The second and third vertical sacrificial layers 116b and 116c may also be formed by stacking the first organic layer ML1, and then applying light and heat together to make the solubility inside the vertical hole OPa and outside the vertical hole OPa different from each other, so that the second and third vertical sacrificial layers 116b and 116c may be formed inside the vertical hole OPa without a planarization process, thereby completing the mold structure.

A method of forming a vertical sacrificial layer using the first organic composition of the present disclosure may also be applied to the process of forming word line contact plugs MC2, as illustrated in FIGS. 8 and 9F - 9O.

A partial etching process of a contact hole in contact with the gate electrodes 130 of the word line contact structure MC2 may be performed (S310).

The partial etching process of the contact hole may form contact holes having different depths exposing all levels of the gate electrodes 130 through additional etchings equal to the number of digits of the binary number when each gate electrode 130 is expressed in binary.

In the semiconductor device 100 of FIG. 7, contact holes in which all the sacrificial insulating layers 118 are exposed may be formed through etchings five times in the sacrificial insulating layer 118 in the stack structure GS.

Specifically, in a first partial etching, etching may be performed to penetrate through the first sacrificial insulating layer 118, in a second partial etching, etching may be performed to simultaneously penetrate through the second sacrificial insulating layer 118, in a third partial etching, etching may be performed to simultaneously penetrate through the fourth sacrificial insulating layer 118, in a fourth partial etching, etching may be performed to simultaneously penetrate through the eighth sacrificial insulating layer 118, and in a fifth partial etching, etching may be performed to simultaneously penetrate through the sixteenth sacrificial insulating layer 118.

24 sacrificial insulating layers 118 may be disposed in the stack structure GS, and contact holes may be formed to expose each of the sacrificial insulating layers 118 in the stack structure GS through five etchings.

For example, a contact hole opening the twenty-fourth sacrificial insulating layer 118 from the upper portion in the stack structure GS may penetrate through the twenty-third (16+4+2+1) layer of sacrificial insulating layers 118, and may be formed by applying the remaining etching processes except for the fourth etching process penetrating through an eighth layer of sacrificial insulating layers 118 among the five etchings.

Specifically, referring to FIGS. 8 and 9F, in a state in which the first to third mold structures MS1 to MS3 are formed, first openings OP1 penetrating through the uppermost interlayer insulating layer and exposing an uppermost sacrificial insulating layer 118 may be formed in positions of all word line contact plugs MC2, using the first photoresist ML2.

In this case, the first photoresist ML2 may be the same material as the first organic layer ML1, but the present disclosure is not limited thereto, and a general photoresist ML2 may be applied thereto. When the first openings OP1 are formed, the first photoresist ML2 may be cleaned and removed.

Referring to FIG. 9G, the first partial etching of the contact hole partial etching process is performed.

The first partial etching may be performed to apply a second photoresist ML3 and expose the applied second photoresist ML3 to light and to open some of the first openings OP1 of the mold structure MS1 to MS3, and second openings OP2 may be formed so as to further penetrate through one layer of the sacrificial insulating layer 118 from a bottom surface of the opened first openings OP1.

The second openings OP2 may extend further by a first depth ha from the first openings OP1. For example, word line contact structures MC2 penetrating through odd gate electrodes 130 within the mold structures MS1 to MS3 may form second openings OP2 by further etching a pair of sacrificial insulating layers 118 and interlayer insulating layers 120 by a first depth ha below the first openings OP1. In this case, a second photoresist ML3 may be filled in the first openings OP1 in which the second openings OP2 are not formed. The second photoresist ML3 may be removed by cleaning after the formation of the second openings OP2.

Referring to FIG. 9H, the second partial etching may be performed to apply a third photoresist ML4 and expose the applied third photoresist ML4 to light, and third openings OP3 may be formed so as to penetrate through two more pairs of the sacrificial insulating layer 118 and the interlayer insulating layer 120 in some of the first openings OP1 and the second openings OP2 of the mold structure MS1 to MS3.

The third openings OP3 may extend further from the first openings OP1 or the second openings OP2 by a second depth hb. In this case, the third photoresist ML4 may be filled in the first and second openings OP1 and OP2 in which the third openings OP3 are not formed. The third photoresist ML4 may be removed by cleaning after the formation of the first and second openings OP1 and OP2.

Referring to FIG. 9I, the third partial etching may be performed to apply a fourth photoresist ML5 and expose the applied fourth photoresist ML5 to light, and fourth openings OP4 may be formed to penetrate further through the sacrificial insulating layer 118 and four pairs of the interlayer insulating layer 120 in some of the first to third openings OP1 to OP3 of the mold structure MS1 to MS3.

The fourth openings OP4 may extend by a third depth hc from the first to third openings OP1 to the third openings OP3. In this case, the fourth photoresist ML5 may be filled in the first to third openings OP1 to OP3 in which the fourth openings OP4 are not formed. The fourth photoresist ML5 may be cleaned and removed.

When the third partial etching is performed, at least some of the fourth openings OP4 may have a long length greater than a predetermined depth.

In a case in which the openings having long lengths, For example, a large aspect ratio, are disposed sporadically, when a photoresist for forming fifth openings OP5 is applied thereafter, a thickness thereof is not uniformly formed in some regions. Accordingly, an error occurs in focus setting during a subsequent exposure, which reduces the reliability of patterning.

To prevent this problem, vertical sacrificial layers may be filled in the openings having a large aspect ratio, and then the photo process may be performed.

Referring to FIG. 9J, the first organic composition described above may be applied onto an upper surface of the mold structure MS to fill the first to fourth openings OP1 to OP4 (S320).

The first organic composition may be prepared, and the first organic composition may be applied onto the mold structure MS from the upper surface of the mold structure MS to fill the first to fourth openings OP1 to OP4.

The first organic composition may be a photoresist organic layer as a positive polymer resin, and may include a polymer resin, a solubility converting agent such as a photo-base generator and a thermal acid generator, and a solvent.

The positive polymer resin may be decomposed under the action of a base, thereby increasing the solubility of the photoresist in an acidic developer. The positive polymer resin may be insoluble or poorly soluble in acidic developer, but the base generated after light irradiation may change a polarity thereof through a deprotection reaction of the polymer side chain, and may become soluble in acidic developer. Examples of polymer resins are as described above.

Both a photo-base generator and a thermal acid generator, which are solubility converting agents, may be included and the photo-base generator and the thermal acid generator may be the same as the first organic layer applied in FIG. 9B.

A general solvent may be applied as the solvent. For example, the solvent may be selected from water, an organic solvent, and mixtures thereof, and may be the same as the first organic layer applied in FIG. 9B.

The first organic composition may be prepared by dissolving a polymer resin in a suitable solvent. The first organic composition may be formed to include 35 wt% of the polymer resin, 60 wt% of the solvent, and 5 wt% of the solubility converting agent, and, among the solubility converting agents, the photo-base generator may be contained in a smaller amount than the thermal acid generator. For example, the photo-base generator may be contained in an amount of 1 wt% and the thermal acid generator may be contained in an amount of 4 wt%, but the present disclosure is not limited thereto.

The first organic composition prepared in this manner may be applied onto the upper surface of the mold structure MS to form the first organic layer.

The formation of the first organic layer may be coated on the substrate by any suitable means, such as spin-coating, slot-die coating, doctor blading, curtain-coating, roller-coating, spray-coating, or dip-coating. The first organic layer may be applied onto the upper surface of the mold structure MS and may thus be formed by filling the first to fourth openings OP1 to OP4.

The first organic layer may be modified to form a vertical contact sacrificial layer ML6f.

As illustrated in FIG. 9J, light may be irradiated toward a first organic layer ML6 on the upper surface of the mold structure MS, and heat may be applied within the photo process (S330).

When both light and heat are injected from an upper portion, a first organic layer ML6’ disposed in an upper portion of the upper surface of the mold structure MS on which light is incident may generate a base by the light, and accordingly, the solubility of the first organic layer ML6’ may change. In this case, when heat is injected together, an acid may be generated from a thermal acid generator contained in a small amount in the first organic material, so that the bases generated in the first organic material may be neutralized. Accordingly, the first organic layer ML6’ on the upper surface of the mold structure MS remains in a state to be dissolved by a solvent such as nBA, which is a low-polarity organic solvent.

In this case, since the first organic layer ML6f in the first to fourth openings OP1 to OP4 has no or very few bases generated because light is not applied, first organic layers in the first to fourth openings OP1 to OP4 may not be neutralized and may be acidified by thermal acid generators. Accordingly, the polymer resin may have hydrophilicity.

Accordingly, among the first organic layers, the first organic layer ML6’ on the upper surface of the mold structure MS may be change to a hydrophobic state with increased solubility in a low-polarity organic solvent such as nBA, and the first organic layer ML6f in the first to fourth openings OP1 to OP4 may be changed to a hydrophilic state, respectively.

The first organic layer ML6’ having increased solubility on the upper surface of the mold structure MS may be removed by cleaning with a nonpolar solvent. Accordingly, the upper surface of the mold structure MS may be exposed, and the first organic layer ML6f in the first to fourth openings OP1 to OP4 may remain as a vertical contact sacrificial layer ML6f so as to have an upper surface substantially similar to the upper surface of the mold structure MS. Accordingly, the planarization may be performed without a separate planarization process.

Referring to FIGS. 8 and 9K, the fourth partial etching may be perform to apply and expose a fifth photoresist ML7, so that the fifth openings OP5 may be formed so as to further penetrate through eight pairs of sacrificial insulating layer 118 and interlayer insulating layer 120 in some of the first to fourth openings OP1 to OP4 of the mold structure MS1 to MS3 (S340).

The fifth photoresist ML7 may be applied to the fifth openings OP5, and light may be applied to an upper region of the vertical contact sacrificial layer ML6f of the first to fourth openings OP1 to OP4 in which the fourth partial etching is to be performed, so that the fifth photoresist ML7 of the corresponding region may be changed to a hydrophilic state.

When the hydrophilic fifth photoresist ML7 is removed by a cleaning process, the vertical contact sacrificial layer ML6f therebelow may be removed at the same time, so that some of the first to fourth openings OP1 to OP4 in which the fourth partial etching is to be performed may be exposed.

Accordingly, an exposed portion of the fifth photoresist ML7 on the mold structure MS and the vertical contact sacrificial layer ML6f may be removed at the same time, thereby simplifying the process.

As illustrated in FIG. 8, some of the first to fourth openings OP1 to OP4 may extend from a bottom surface thereof by a fourth depth hd (S350). In this case, vertical contact sacrificial layers ML6f may remain in the first to fourth openings OP1 to OP4 in which the fifth openings OP5 are not formed. The fifth photoresist ML7 may be removed by cleaning after the formation of the fifth openings OP5.

Referring to FIG. 8, operation S320 to S350 may be repeated to perform etching to a final depth of each contact plug MC2.

Specifically, referring to FIG. 9l, the second organic layer may be applied onto the upper surface of the mold structure MS to fill the fifth openings OP5.

A second organic composition may be prepared, and the second organic composition may be applied onto the mold structure MS so as to fill the fifth openings OP5 from the upper surface of the mold structure MS. The second organic composition may have the same composition as the first organic composition of FIG. 9J. The second organic composition may be applied onto the upper surface of the mold structure MS to form a second organic layer.

The second organic layer may be applied to the upper surface of the mold structure MS and may thus be formed by filling the fifth openings OP5.

The second organic layer may be modified to proceed with a vertical contact sacrificial layer ML8f.

As illustrated in FIG. 9l, light may be irradiated toward a second organic layer ML8 and heat may be applied to the upper surface of the mold structure MS.

When both light and heat are injected from an upper portion, the second organic layer ML8 disposed on the upper surface of the mold structure MS where light is incident may generate a base by the light, and acids may be generated by the heat and may be mutually neutralized, so that a second organic layer ML8’ on the upper surface of the mold structure MS may be converted to a hydrophobic state, and since the second organic layer ML8f within the fifth openings OP5 has no or very few bases generated because light is not applied, the second organic layer ML8f in the fifth openings OP5 may not be neutralized and may be acidified by the thermal acid generators. Accordingly, the polymer resin may have hydrophilicity.

Referring to FIG. 9M, the second organic layer ML8 having increased solubility on the upper surface of the mold structure MS may be removed by cleaning with a nonpolar solvent. Accordingly, the upper surface of the mold structure MS may be exposed, and the first organic layer ML6f and second organic layer ML8f having hydrophilicity may remain as vertical contact sacrificial layers ML6f and ML8f in the first to fifth openings OP1 to OP5 so as to have an upper surface of substantially a similar level to the upper surface of the mold structure MS. Accordingly, the planarization may be performed without a separate planarization process.

Next, referring to FIG. 8 and FIG. 9N, a sixth photoresist ML9 may be applied and exposed to light, so that sixth openings OP6 may be formed to penetrate through sixteen pairs of sacrificial insulating layer 118 and interlayer insulating layer 120 in some of the first to fifth openings OP1 to OP5 of the mold structure MS1 to MS3.

The sixth photoresist ML9 may be applied to the sixth openings OP6, and light may be applied to light to an upper region of a vertical contact sacrificial layer of the first to fifth openings OP1 to OP5 in which the fifth partial etching is to be performed, so that the sixth photoresist ML9 of the corresponding region may be changed to a hydrophilic state.

When the hydrophilic sixth photoresist ML9 is removed by the cleaning process, the vertical contact sacrificial layers ML6f and ML8f therebelow may be removed at the same time, so that some of the first to fifth openings OP1 to OP5 where the fifth partial etching is to be perform ed may be exposed.

Accordingly, an exposed portion of the sixth photoresist ML9 on the mold structure MS and the vertical contact sacrificial layers ML6f and ML8f may be removed at the same time, thereby simplifying the process.

In this manner, some of the first to fifth openings OP1 to OP5 may extend from bottom surfaces thereof further by a fifth depth he. In this case, the vertical contact sacrificial layers ML6f and ML8f may remain in the first to fifth openings OP1 to OP5 in which the sixth openings OP6 are not formed.

The sixth photoresist ML9 may be cleaned and removed after the formation of the sixth openings OP6, and when the fifth partial etching is completed, all contact holes may be formed up to a depth for each word line contact plug MC2.

When the partial etching for the contact holes is completed, all of the vertical contact sacrificial layers ML6f and ML8f of the first to sixth openings OP1 to OP6 may be removed, and the contact holes may be opened.

Referring to FIGS. 8 and 9O, preliminary contact insulating layers 160P and contact sacrificial layers 161 may be formed in contact holes (S360).

The preliminary contact insulating layers 160P may be conformally formed to cover sidewalls and bottom surfaces of the contact holes. For example, the preliminary contact insulating layers 160P may be formed using an atomic layer deposition (ALD) or chemical vapor deposition (CVD) process.

The contact sacrificial layers 161 may be formed to fill the contact holes on the preliminary contact insulating layers 160P. The contact sacrificial layers 161 may include a different material from the preliminary contact insulating layers 160P, and may include, for example, carbon (C).

Referring to FIG. 8 and FIG. 9P, some of the vertical sacrificial structures 116 may be removed to form channel structures CH (S370).

A mask layer exposing only a region corresponding to the channel structures CH in the memory region R1 may be formed, and the exposed vertical sacrificial structures 116 may be removed to form channel holes. At least a portion of the channel dielectric layer 145, the channel layer 140, a channel buried insulating layer and the channel pad 149 may be sequentially deposited in channel holes to form the channel structures CH.

The channel dielectric layer 145 may be formed to have a uniform thickness using an ALD or CVD process. The channel dielectric layer 145 may be formed in whole or in part in this operation, and a portion extending vertically along the channel structures CH to the conductive layer 101 may be formed in this operation. The channel layer 140 may be formed on the channel dielectric layer 145 within the channel holes. The channel buried insulating layer may be formed to fill the channel holes and may be formed of an insulating material. The channel pad 149 may be formed of a conductive material, and may be formed of, for example, polycrystalline silicon.

Additionally, a portion of the vertical sacrificial structures 116 may be removed to form the support structures DH.

A mask layer exposing a region corresponding to the support structures DH in the string selection region R3 and the extension region R2 may be formed, and dummy holes may be formed by removing the exposed vertical sacrificial structures 116. A process of expanding the dummy holes by removing a portion of the mold structure around the dummy holes may be performed. The expanded dummy holes may be filled with an insulating material to form the support structures DH.

The sacrificial insulating layers 118 may be removed and gate electrodes 130 may be formed.

Separation openings exposing regions corresponding to the separation regions may be formed. The sacrificial insulating layers 118 exposed through the separation openings may be removed. The sacrificial insulating layers 118 may be selectively removed with respect to the interlayer insulating layers 120, the channel structures CH, the support structures DH, and the preliminary contact insulating layers 160P, for example, using wet etching.

The gate electrodes 130 may be formed by depositing a conductive material in regions from which the sacrificial insulating layers 118 are removed. The conductive material may include a metal, polycrystalline silicon, or a metal silicide material. In the gate electrodes 130, after forming the diffusion barrier layers, the gate electrodes 130 may be formed by depositing a conductive material. In some example implementations, a portion of the channel dielectric layer 145 may be formed before forming the gate electrodes 130. Accordingly, a stack structure GS including the first to third stack structures GS1 to GS3 may be formed.

As illustrated in FIG. 8 and FIG. 9Q, contact structures MC1 and MC2 may be formed (S380). Specifically, after the contact sacrificial layers 161 are selectively removed with respect to the preliminary contact insulating layers 160P, some of the exposed preliminary contact insulating layers 160P may be removed to form the contact insulating layers 160.

For example, after the contact sacrificial layers 161 are removed, some of the exposed preliminary contact insulating layers 160P may be removed from bottom surfaces thereof. When the preliminary contact insulating layers 160P are removed, some of the exposed gate electrodes 130 may also be recessed from upper surfaces thereof. Accordingly, contact insulating layers 160 disposed only on sidewalls of the contact holes may be formed. A conductive material may be deposited in the contact holes to form word line contact plugs MC2. The word line contact plugs MC2 may be physically connected to the gate electrodes 130 allocated below, respectively. In this case, string selection contact plugs MC1 may also be formed in the string selection region R3.

Referring to FIG. 7, upper interconnection structures 185 and 180 may be formed on the stack structures GS1 to GS3. After forming the cell region insulating layer 150, studs 185 and cell interconnection lines 180 may be formed. The studs 185 may be formed by forming stud holes penetrating through the cell region insulating layer 150 and exposing channel structures CH and contact plugs MC1 and MC2, and then filling the stud holes with a conductive material. Cell interconnection lines 180 may be formed on the studs 185. An upper insulating layer 190 may be further formed on the cell interconnection lines 185. The base substrate SUB may be removed, and the channel layers 140 may be exposed.

The base substrate SUB may be removed, and some of the exposed channel dielectric layers 145 may be removed to expose the channel layers 140. By forming a conductive layer 101 connected to the channel layers 140, the semiconductor device 100 of FIG. 7 may be manufactured. In some example implementations, the conductive layer 101 may be formed as a conformal layer along upper ends of the channel structures CH and upper ends of the support structures DH.

Hereinafter, another method of forming vertical contact sacrificial layers is described.

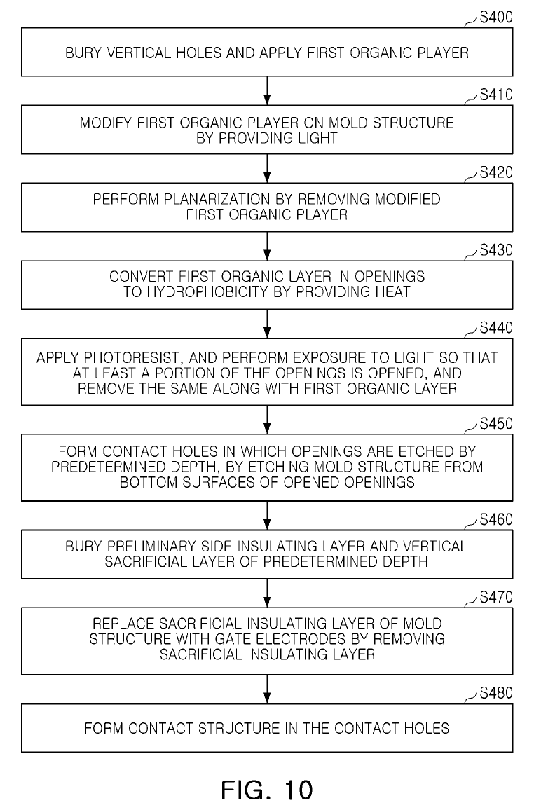

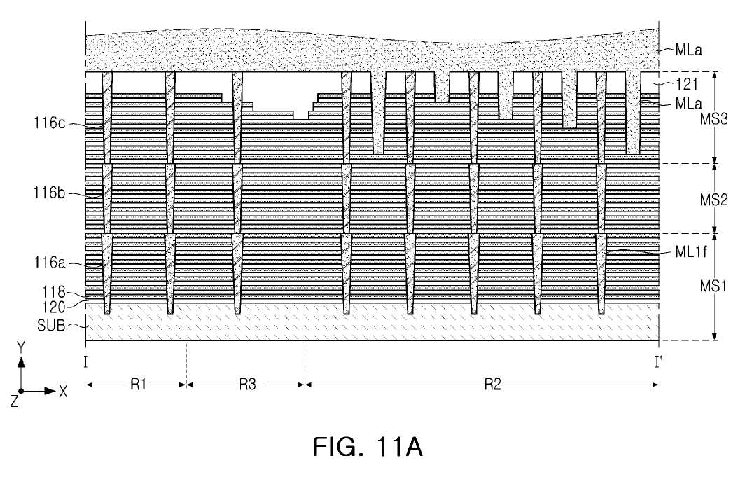

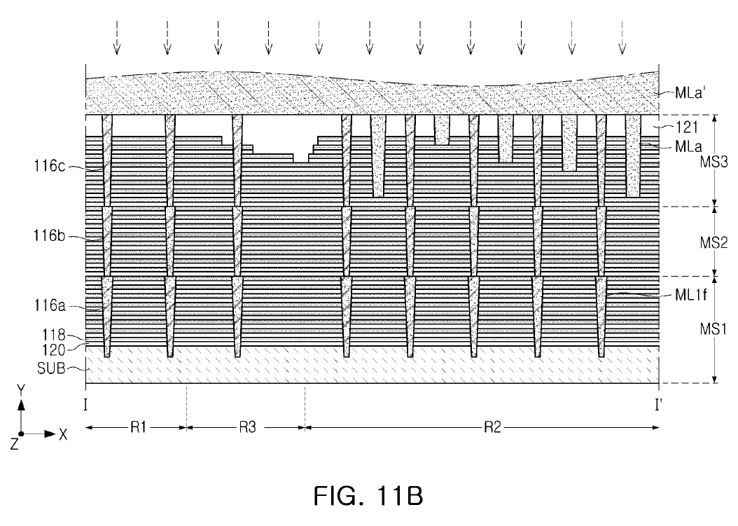

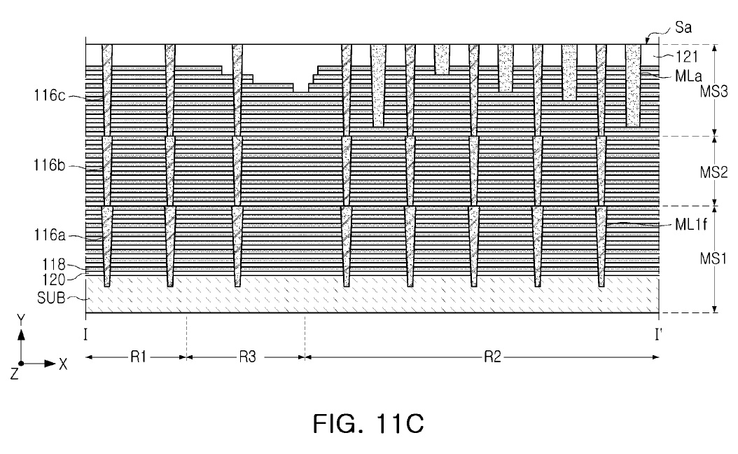

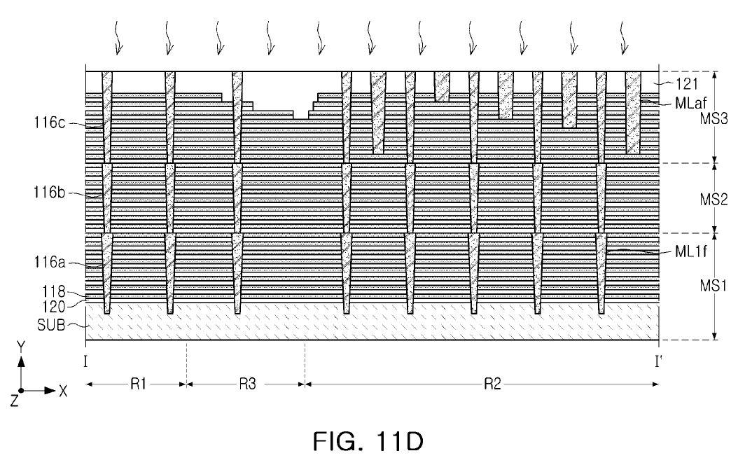

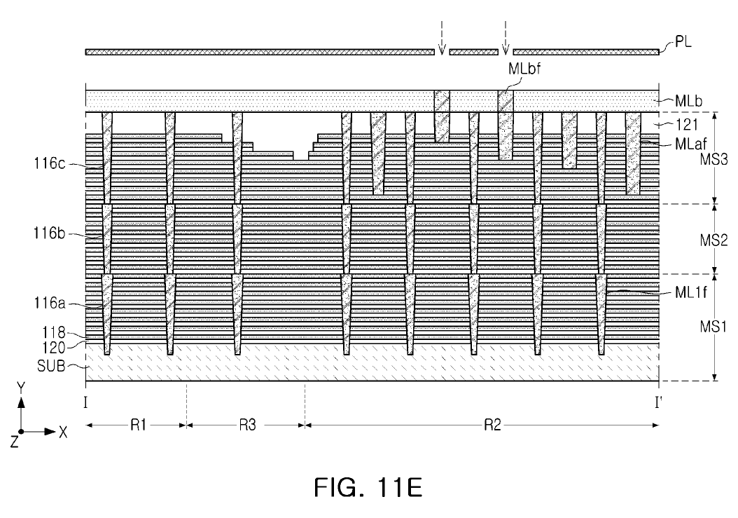

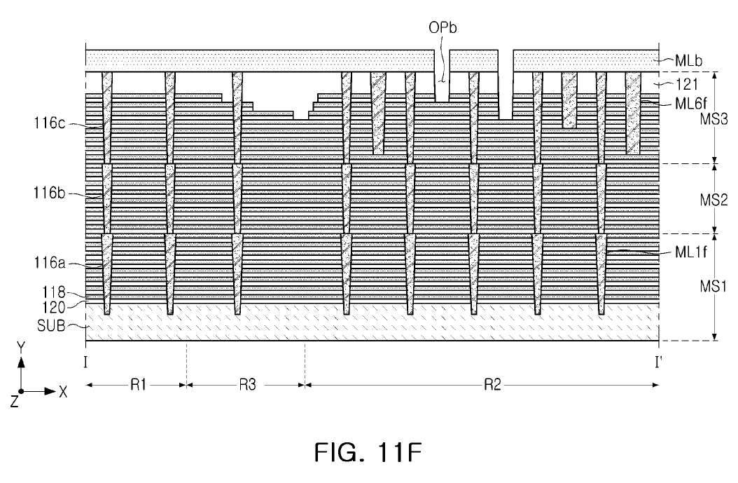

FIG. 10 is a flowchart illustrating another method of manufacturing the semiconductor device of FIG. 7, and FIGS. 11A-11F are schematic cross-sectional views illustrating a method of manufacturing the semiconductor device of FIG. 10.

An operation of forming a vertical contact sacrificial layer according to an example implementation is a modified example of FIG. 9J in which a vertical contact sacrificial layer is formed after processes of FIGS. 8 - 9A - 9I are performed.

For example, when the third partial etching is performed as in FIG. 9I, at least some of the fourth openings OP4 may have a length longer than a predetermined depth.

In the case in which openings OP4 having long lengths, For example, a large aspect ratio, are disposed sporadically, when a photoresist is applied to form the fifth openings OP5 thereafter, a thickness may not be uniformly formed in some regions. Accordingly, errors in focus setting occur during subsequent exposure, resulting in errors in patterning.

To prevent this problem, vertical contact sacrificial layers are buried in openings having a large aspect ratio, and may then be planarized, and then the subsequent photo process may be performed thereon. Throughout this application, the term “large aspect ratio” or “high aspect ratio” may refer to an aspect ratio greater than 5:1, greater than 10:1, and/or greater than 20:1. In some implementations, the term “large aspect ratio” or “high aspect ratio” may refer to an aspect ratio between 5:1 and 20:1, between 10:1 and 20:1, or between 15:1 and 20:1.

Referring to FIGS. 10 and 11A, a first organic layer MLa may be applied onto the upper surface of the mold structure MS to fill the first to fourth openings OP (S400).

The first organic layer MLa may be prepared, and the first organic layer MLa may be applied onto the mold structure MS to fill the first to fourth openings OP1 to OP4 from the upper surface of the mold structure MS.

The first organic layer MLa is a photoresist organic layer as a positive polymer resin,, and may include a polymer resin, a solubility converting agent such as a photoacid generator and a thermal acid generator, and a solvent. Since the first organic composition forming the first organic layer MLa is the same as the first organic composition of FIG. 5 and FIG. 6a, descriptions thereof will be omitted.

The first organic composition may be applied onto the upper surface of the first mold structure MS to form the first organic layer MLa.

The first organic layer MLa may be applied onto the upper surface of the mold structure MS, and may thus be formed by filling the first to fourth openings OP1 to OP4.

Referring to FIG. 10 and FIG. 11B, the first organic layer MLa may be modified to proceed with the vertical contact sacrificial layer (S410).

As illustrated in FIG. 11B, light may be irradiated onto the upper surface of the mold structure MS toward the first organic layer MLa. A first organic layer MLa’ disposed on the upper surface of the mold structure MS on which light is incident may generate acid due to light, and accordingly, the solubility of the first organic layer MLa’ may be changed and may be change to a hydrophilic state.

The first organic layer MLa in the first to fourth openings OP1 to OP4 may maintain an original hydrophobic state thereof, so that the characteristics of the first organic layer MLa may be different depending on the position, and thus the solubility may vary.

Referring to FIGS. 10 and 11C, the first organic layer MLa’ on the upper surface of the mold structure MS may be removed using a polar organic solvent (S420). Accordingly, the first organic layer MLa’ having increased solubility on the upper surface of the mold structure MS may be removed by cleaning with a polar solvent. Accordingly, the upper surface of the mold structure MS may be exposed, and the first organic layer MLa having hydrophobicity may remain as a vertical contact sacrificial layer within the first to fourth openings OP1 to OP4 so as to have an upper surface substantially similar to the upper surface of the mold structure MS. Accordingly, the planarization may be performed without a separate planarization process, and the process may be performed within photo equipment, like the subsequent photo process, which is economical.

Referring to FIG. 10 and FIG. 11D, the remaining first organic layer MLaf may be modified by injecting heat (S430). Since the first organic layer MLaf generates acid from the thermal acid generator, and the first organic materials in the first to fourth openings OP1 to OP4 do not have any acid or only a small amount of acid because light is not applied, the first organic materials MLaf in the first to fourth opening layers OP1 to OP4 may be acidified by the thermal acid generators. Accordingly, the polymer resin may be modified into a vertical contact sacrificial layer MLaf having hydrophilicity.

Referring to FIG. 10 and FIG. 11E, a photoresist MLb may be applied, and light may be applied to an upper region of the vertical contact sacrificial layer MLaf of the first to fourth openings OP1 to OP4 in which the fourth partial etching is to be performed through a photomask PL, so that the photoresist MLb in a corresponding region MLbf may be changed to a hydrophilic state (S440).

Referring to FIG. 11F, when removing the hydrophilic photoresist region MLbf by the cleaning process using a polar solvent, the vertical contact sacrificial layer MLaf therebelow may be removed simultaneously, so that some of openings OPb, among the first to fourth openings OP1 to OP4 to be subjected to the fourth partial etching, may be exposed. Accordingly, the exposed region MLbf of the photoresist on the mold structure MS and the vertical contact sacrificial layer MLaf may be removed simultaneously, thereby simplifying the process.

Referring to FIG. 10 and FIG. 9K, the fourth depth hd may extend from a bottom surface of some of the opened openings OP1 to OP4 (S450). In this case, vertical contact sacrificial layers MLaf may remain in the first to fourth openings OP1 to OP4 in which the fifth openings OP5 are not formed. The fifth photoresist ML7 may be removed by cleaning after the formation of the fifth openings OP5.

Then, after additionally performing a process for the fifth partial etching, referring to FIG. 10 and FIG. 9o, preliminary contact insulating layers 160P and contact sacrificial layers 161 may be formed in the contact holes (S460).

The preliminary contact insulating layers 160P may be conformally formed to cover sidewalls and bottom surfaces of the contact holes. For example, the preliminary contact insulating layers 160P may be formed using an atomic layer deposition (ALD) or chemical vapor deposition (CVD) process.

The contact sacrificial layers 161 may be formed to fill the contact holes on the preliminary contact insulating layers 160P. The contact sacrificial layers 161 may include a different material from the preliminary contact insulating layers 160P, and may include, for example, carbon (C).

Referring to FIG. 10 and FIG. 9P, a portion of the vertical sacrificial structures 116 may be removed and channel structures CH may be formed (S470). Additionally, a portion of the vertical sacrificial structures 116 may be removed and support structures DH may be formed. The sacrificial insulating layers 118 may be removed and gate electrodes 130 may be formed. Separation openings exposing regions corresponding to the separation regions may be formed. The sacrificial insulating layers 118 exposed through the separation openings may be removed. The sacrificial insulating layers 118 may be selectively removed, for example, using wet etching, with respect to the interlayer insulating layers 120, the channel structures CH the support structures DH, and the preliminary contact insulating layers 160P.

The gate electrodes 130 may be formed by depositing a conductive material in the regions from which the sacrificial insulating layers 118 are removed. The conductive material may include a metal, polycrystalline silicon, or a metal silicide material. In the gate electrodes 130, after forming the diffusion barrier layers, the gate electrodes 130 may be formed by depositing a conductive material. In some example implementations, a portion of the channel dielectric layer 145 may be formed before forming the gate electrodes 130. Accordingly, the stack structure GS including the first to third stack structures GS1 to GS3 may be formed.

As illustrated in FIG. 10 and FIG. 9Q, contact structures MC1 and MC2 may be formed (S480). Specifically, after selectively removing the contact sacrificial layers 161 with respect to the preliminary contact insulating layers 160P, some of the exposed preliminary contact insulating layers 160P may be removed to form the contact insulating layers 160.

For example, after removing the contact sacrificial layers 161, some of the exposed preliminary contact insulating layers 160P may be removed from bottom surfaces thereof. When removing the preliminary contact insulating layers 160P, the exposed gate electrodes 130 may also be partially recessed from upper surfaces thereof. Accordingly, the contact insulating layers 160 disposed only on sidewalls of the contact holes may be formed. A conductive material may be deposited in the contact holes to form the word line contact plugs MC2. The word line contact plugs MC2 may be physically connected to the gate electrodes 130 allocated below, respectively. In this case, the string selection contact plugs MC1 may also be formed within the string selection region R3.

Referring to FIG. 7, the upper interconnection structure 185 and 180 may be formed on the stack structures GS1 to GS3. After the cell region insulating layer 150 is formed, the studs 185 and the cell interconnection lines 180 may be formed. The studs 185 may be formed by forming stud holes penetrating through the cell region insulating layer 150 and exposing the channel structures CH and the contact plugs MC1 and MC2, and then filling the stud holes with a conductive material. The cell interconnection lines 180 may be formed on the studs 185. An upper insulating layer 190 may be further formed on the cell interconnection lines 185. The base substrate SUB may be removed, and the channel layers 140 may be exposed.

As used herein, “about,” “approximately,” “generally,” and “substantially” are understood to refer to numbers in a range of numerals, for example the range of -10% to +10% of the referenced number, preferably -5% to +5% of the referenced number, more preferably -1% to +1% of the referenced number, most preferably -0.1% to +0.1% of the referenced number. Moreover, any numerical ranges disclosed herein should be interpreted as providing support for any specific value or sub-range within the stated range. For example, a disclosure of a range from 1 to 10 supports sub-ranges such as 1 to 5, 3 to 6, 1 to 9, 2.5 to 4.7, 2.2 to 9.9, and so on.

While the present disclosure contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The present disclosure is not limited to the above-described implementations and the accompanying drawings but is defined by the appended claims. In addition, various modifications and modifications may be made within an equivalent scope of the technical idea of the present disclosure and the scope of claims to be described below by a person skilled in the technical field to which this disclosure belongs.

What is claimed is:

1. A method of manufacturing one or more semiconductor devices, the method comprising:
sequentially forming an interlayer insulating layer and an upper insulating layer on a substrate;
forming first openings by sequentially penetrating through the upper insulating layer and the interlayer insulating layer;
applying a first organic material and filling the first openings, wherein the first organic material includes a first portion within the first openings and a second portion on the upper insulating layer;
changing solubility of the first organic material according to a position of the first organic material;
selectively removing the second portion of the first organic material on the upper insulating layer;
applying a second organic material on the upper insulating layer;
changing solubility of the second organic material in a first region overlapping the first openings by providing light to the second organic material;
forming open regions by removing the first portion of the first organic material within the first openings and the second organic material in the first region together; and
forming a vertical structure filling the open regions.

2. The method of manufacturing one or more semiconductor devices of claim 1, wherein the first region completely covers the first openings.

3. The method of manufacturing one or more semiconductor devices of claim 1, wherein the first organic material includes a polymer resin, a solubility converting agent, and a solvent.

4. The method of manufacturing one or more semiconductor devices of claim 3, wherein the first organic material includes 60 wt% of the solvent, 35 wt% of the polymer resin, and 5 wt% of the solubility converting agent.

5. The method of manufacturing one or more semiconductor devices of claim 3, wherein the solubility converting agent includes a photo-base generator and a thermal acid generator.

6. The method of manufacturing one or more semiconductor devices of claim 5, wherein an amount of the thermal acid generator is greater than an amount of the photo-base generator.

7. The method of manufacturing one or more semiconductor devices of claim 5, wherein a weight ratio of the photo-base generator to the thermal acid generator is 1:4.

8. The method of manufacturing one or more semiconductor devices of claim 1, wherein both light and heat are applied to the second portion of the first organic material on the upper insulating layer, and the heat is applied to the first portion of the first organic material within the first openings.

9. The method of manufacturing one or more semiconductor devices of claim 8, wherein the second portion of the first organic material on the upper insulating layer has hydrophobicity after the light and the heat are applied, and the first portion of the first organic material within the first openings has hydrophilicity after the heat is applied.

10. The method of manufacturing one or more semiconductor devices of claim 1, wherein the second organic material includes a polymer resin, a solubility converting agent, and a solvent, and
wherein the solubility converting agent of the second organic material includes a photo-base generator.

11. The method of manufacturing one or more semiconductor devices of claim 3, wherein the solubility converting agent includes a photo acid generator and a thermal acid generator.

12. The method of manufacturing one or more semiconductor devices of claim 11, wherein the changing solubility of the first organic material includes:
changing the second portion of the first organic material to have hydrophilicity by applying light to the second portion of the first organic material; and
removing only the second portion of the first organic material having the hydrophilicity with a polar organic solvent.

13. The method of manufacturing one or more semiconductor devices of claim 12, comprising:
applying heat to the first portion of the first organic material within the first openings to change the first organic materials to have the hydrophilicity.

14. A method of manufacturing one or more semiconductor devices, the method comprising:
forming an interlayer insulating layer on a substrate,
forming an upper insulating layer on the interlayer insulating layer;
forming first openings by penetrating through the upper insulating layer and the interlayer insulating layer;
applying a first organic material;
filling the first openings with the first organic material, wherein the first organic material includes a first portion within the first openings and a second portion on the upper insulating layer;
changing solubility of the first organic material according to a position of the first organic material;
selectively removing the second portion of the first organic material on the upper insulating layer;
applying a second organic material on the upper insulating layer;
changing solubility of the second organic material in a first region overlapping the first openings by providing light to the second organic material;
forming open regions by removing the first portion of the first organic material within the first openings and the second organic material in the first region together; and
forming a vertical structure filling the open regions,
wherein the first organic material includes a polymer resin, a solubility converting agent, and a solvent,
wherein the solubility converting agent includes a photo-base generator and a thermal acid generator.

15. A method of manufacturing one or more semiconductor devices, comprising:
forming a mold structure by alternately stacking sacrificial insulating layers and interlayer insulating layers in a first direction;
forming first openings from an upper surface of the mold structure; applying a first organic material and filling the first openings, wherein the first organic material includes a first portion within the first openings and a second portion on the mold structure;
changing solubility of the first organic material according to a position of the first organic material;
selectively removing the second portion of the first organic material on the mold structure;
applying a photoresist on the mold structure;
changing solubility of the photoresist in a first region overlapping a portion of the first openings by providing light to the photoresist;
forming second openings by removing the first region of the photoresist and the first portion of the first organic material within the first openings under the first region together;
forming sacrificial layers filling the second openings;
replacing the sacrificial insulating layers with gate electrodes; and
forming contact plugs in contact with the gate electrodes by removing the sacrificial layer.

16. The method of manufacturing one or more semiconductor devices of claim 15, wherein the forming the first openings includes:
performing a photo process of opening a portion of preliminary openings formed from the upper surface of the mold structure; and
forming the first openings by etching the interlayer insulating layers and the sacrificial insulating layers by a predetermined depth from a lower surface of the preliminary openings.

17. The method of manufacturing one or more semiconductor devices of claim 16, wherein the forming the first openings includes:
etching the sacrificial insulating layers from the lower surface of the preliminary openings.

18. The method of manufacturing one or more semiconductor devices of claim 15, wherein the first organic material includes a polymer resin, a thermal acid generator, a solvent, and at least one of a photo-base generator or a photo-acid generator.

19. The method of manufacturing one or more semiconductor devices of claim 18, wherein an amount of the thermal acid generator is greater an amount of the photo-base generator or an amount of the photo-acid generator.

20. The method of manufacturing one or more semiconductor devices of claim 17, wherein a weight ratio of the photo-base generator to the thermal acid generator is 1:4.
